(19) United States
(12) Patent Application Publication
(10) Pub. No.: US 2024/0421141 A1
(43) Pub. Date: Dec. 19, 2024

(54) HIGH PERFORMANCE COMPUTING DEVICE AND METHOD OF MANUFACTURING THE SAME

(71) Applicant: AP MEMORY TECHNOLOGY CORPORATION, HSINCHU COUNTY (TW)

(72) Inventor: WEN-LIANG CHEN, HSINCHU COUNTY (TW)

(21) Appl. No.: 18/642,563

(22) Filed: Apr. 22, 2024

Related U.S. Application Data
(60) Provisional application No. 63/508,635, filed on Jun. 16, 2023.

(51) Int. Cl. H01L 25/18; H01L 23/00; H01L 23/48; H01L 23/528; H01L 25/00

(52) U.S. Cl. CPC H01L 25/18; H01L 23/481; H01L 23/5286; H01L 24/08; H01L 24/13; H01L 24/16; H01L 25/50; H01L 2224/08145; H01L 2224/08146; H01L 2224/13025; H01L 2224/13111; H01L 2224/13113; H01L 2224/13116; H01L 2224/13139; H01L 2224/13144; H01L 2224/13147; H01L 2224/13155; H01L 2224/16145

(57) ABSTRACT

A semiconductor device includes a first substrate and a second substrate. The first substrate has a plurality of first-type transistors formed of planar-type transistors or fin-type transistors, wherein a gate silicon oxide layer of each of the planar-type transistors has a first thickness, and a gate silicon oxide layer of each of the fin-type transistors has a second thickness. The second substrate is bonded to the first substrate and including a plurality of second-type transistors formed of gate-all-around (GAA) transistors, wherein a gate silicon oxide layer of each of the GAA transistors has a third thickness. The third thickness is less than the first thickness or the second thickness.

### PRIORITY CLAIM AND CROSS-REFERENCE

This application claims priority to U.S. Provisional Application No. 63/508,635 filed Jun. 16, 2023, the disclosure of which are hereby incorporated by reference in its their entirety.

### BACKGROUND

In advanced semiconductor manufacturing technologies, the continuing reduction in device size and increasingly complex circuit arrangements have made the design and fabrication of integrated circuits (ICs) more challenging and costly. In the ongoing pursuit of better device performance with smaller footprint and lower power consumption, advanced semiconductor manufacturing techniques that allow reduced line widths, including techniques that use gate-all-around (GAA) transistors, have been explored. The GAA transistor may be used in a structure that is significantly different from those of its predecessors in that the channel current can be manipulated in a more efficient and controllable manner so as to improve the electrical performance of the device that includes the GAA transistor.

While there have certainly been some improvements in the techniques used for manufacturing GAA transistor-based semiconductor devices, such techniques still fall short of meeting market demands. For example, the ongoing attempts to reduce device size in advanced applications create difficulties in the integration of semiconductor devices. High performance computing (HPC) device such as a graphic processing unit (GPU) chip requires high speed and low power transistors which forms on a GAA chip. Core circuit of the GAA chip mainly serves for computing purpose while the non-core circuit of the GAA chip (e.g., I/O circuit) is to facilitate operation of the core circuit. However, non-core circuit of the GAA chip requires a thick gate dielectric material in order to meet requirements for large voltage drop, whereas the limited inter-nanosheet spacing between each semiconductor channel material nanosheet of the core circuit cannot accommodate the thick gate dielectric material.

Therefore, there is a need to address integration issues for the manufacturing of the GAA transistor-based semiconductor devices.

### SUMMARY

According to one aspect of the present disclosure, a semiconductor device includes: a first substrate including a plurality of first-type transistors formed of planar-type transistors or fin-type transistors, wherein a gate silicon oxide layer of each of the planar-type transistors has a first thickness, and a gate silicon oxide layer of each of the fin-type transistors has a second thickness; and a second substrate bonded to the first substrate and including a plurality of second-type transistors formed of gate-all-around (GAA)-type transistors, wherein a gate silicon oxide layer of each of the GAA-type transistors has a third thickness. The third thickness is less than the first thickness or the second thickness.

According to one aspect of the present disclosure, a semiconductor device includes: a first substrate including a plurality of first-type transistors formed of planar-type or fin-type transistors, wherein the first-type transistors operate under a first voltage and wherein each of the plurality of first-type transistors has a first gate silicon oxide layer stacking with a first high-k dielectric layer, the first gate silicon oxide layer and the first high-k dielectric layer having a first combined thickness; and a second substrate bonded to the first substrate and including a plurality of second-type transistors formed of gate-all-around (GAA) transistors, wherein the second-type transistors operate under a second voltage less than the first voltage and wherein each of the plurality of second-type transistors has a second gate silicon oxide layer stacking with a second high-k dielectric layer, the second gate silicon oxide layer and the second high-k dielectric layer having a second combined thickness. The first combined thickness is greater than the second combined thickness.

According to one aspect of the present disclosure, a method includes: forming a plurality of first die regions on a first semiconductor wafer, wherein each of the first die regions comprises a plurality of first-type transistors formed of planar-type transistors or fin-type transistors, wherein a gate silicon oxide layer of each of the planar-type transistors has a first thickness, and a gate silicon oxide layer of each of the fin-type transistors has a second thickness; forming a first interconnection area adjacent to the first die regions; forming a plurality of second die regions on a second semiconductor wafer, wherein each of the second die regions comprises a plurality of second-type transistors formed of gate-all-around (GAA) transistors, wherein a gate silicon oxide layer of each of the GAA transistors has a third thickness; forming a second interconnection area adjacent to the second die regions; and bonding the first semiconductor wafer and the second semiconductor wafer by electrically coupling each of the first die regions to a corresponding one of the second die regions. The third thickness is less than the first thickness or the second thickness.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A, 1B and 1C are perspective views of several types of transistors, in accordance with some embodiments of the present disclosure.

FIG. 2 is a schematic cross-sectional view of the transistor shown in FIG. 1C, in accordance with some embodiments of the present disclosure.

FIG. 3A is a schematic top view of a first semiconductor wafer in accordance with some embodiments of the present disclosure.

FIG. 3B is a schematic top view of a second semiconductor wafer in accordance with some embodiments of the present disclosure

FIGS. 4A, 4B, 4C, 4D, 4E, 4F and 4G are schematic cross-sectional views of intermediate stages of a method of forming the first semiconductor wafer shown in FIG. 3A, in accordance with some embodiments of the present disclosure.

FIG. 5 is a schematic cross-sectional view of the first semiconductor wafer shown in FIG. 3A, in accordance with some embodiments of the present disclosure.

FIGS. 6A and 6B are schematic cross-sectional view of the second semiconductor wafer shown in FIG. 3B, in accordance with some embodiments of the present disclosure.

FIG. 7 is a schematic cross-sectional view of a semiconductor structure, in accordance with some embodiments of the present disclosure.

FIGS. 8A and 8B are schematic cross-sectional views of intermediate stages of a method of bonding the first semiconductor wafer to the second semiconductor wafer, in accordance with some embodiments of the present disclosure.

FIG. 9 is a schematic cross-sectional view of a semiconductor structure, in accordance with some embodiments of the present disclosure.

FIG. 10 is a schematic cross-sectional view of a semiconductor structure, in accordance with some embodiments of the present disclosure.

FIG. 11 is a schematic cross-sectional view of a semiconductor structure, in accordance with some embodiments of the present disclosure.

FIG. 12 is a schematic cross-sectional view of a semiconductor structure, in accordance with some embodiments of the present disclosure.

FIGS. 13A, 13B, 13C and 13D are schematic cross-sectional views of intermediate stages of a method of bonding the second semiconductor wafer to the first semiconductor wafer, in accordance with some embodiments of the present disclosure.

FIG. 14 is a schematic cross-sectional view of a semiconductor structure, in accordance with some embodiments of the present disclosure.

FIG. 15 is a schematic diagram showing a transmission path of power and signals of a semiconductor device, in accordance with some embodiments of the present disclosure.

FIG. 16 is a schematic diagram showing a transmission path of power and signals of a semiconductor device, in accordance with some embodiments of the present disclosure.

FIG. 17 is a schematic diagram showing a transmission path of power and signals of a semiconductor device, in accordance with some embodiments of the present disclosure.

FIG. 18 is a schematic diagram showing a transmission path of power and signals of a semiconductor device, in accordance with some embodiments of the present disclosure.

FIG. 19 is a schematic diagram showing a transmission path of power and signals of a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described in the present disclosure in order to facilitate understanding of the invention. Such examples are merely provided to aid in understanding and are not intended to limit the present disclosure. For example, the formation of a first feature over or on a second feature as described herein may include embodiments in which the first and second features are formed in direct contact, and may also include embodiments in which additional features are formed between the first and second features, such that the first and second features are not in direct contact. In addition, the present disclosure may repeat reference numerals and/or letters in the various examples. Such repetition is for the purpose of simplicity and clarity and does not necessarily indicate a relationship between the various embodiments and/or configurations described.

Further, spatially relative terms, such as “beneath,” “below,” “lower,” “above,” “upper” and the like, may be used herein for ease of description to describe one element or feature's relationship to another element(s) or feature(s) as illustrated in the figures. Such spatially relative terms are intended to encompass different orientations of the device in use or operation in addition to the orientation depicted in the figures. The apparatus may be otherwise oriented (for example, rotated 90 degrees from the depicted orientation) and the spatially relative descriptors used herein should accordingly be interpreted as including other orientations.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “approximately” or “substantially” may mean within some small percentage of a given value or range. Alternatively, the terms “about,” “approximately” or “substantially” mean within an acceptable standard error of the value indicated when considered by one of ordinary skill in the art. Unless expressly specified otherwise, all of the numerical ranges, amounts, values and percentages such as those for quantities of materials, durations of time, temperatures, operating conditions, ratios of amounts, and the likes thereof disclosed herein should be understood as modified in all instances by the terms “about,” “approximately” or “substantially.” Accordingly, unless indicated otherwise, the numerical parameters set forth in the present disclosure and attached claims are approximations that can vary. At the very least, each numerical parameter should be construed in light of the number of reported significant digits and by applying ordinary rounding techniques. Ranges are expressed herein as from one endpoint to another endpoint, or as between one endpoint and another endpoint. All ranges disclosed herein are inclusive of the endpoints, unless specified otherwise.

The present disclosure relates generally to a semiconductor structure or a semiconductor device, and more particularly to a structure or a device combining different circuits manufactured using different transistor generations to improve device performance and reduce integration cost. The present disclosure discusses various embodiments that include two types of transistors, i.e., a gate-all-around (GAA) transistor and a non-GAA (nGAA) transistor. The GAA transistor can include a nanosheet transistor or a nanowire transistor, and the nGAA transistor can include a planar-type transistor or a fin-type transistor; however, the present disclosure is not limited thereto. Any variation of the abovementioned transistors can be categorized either as a GAA transistor or an nGAA transistor. For example, nGAA transistors include planar field-effect transistors, planar bipolar junction transistors, planar transistors with raised source/drain regions, vertical transistors, and the like. Likewise, GAA transistors include horizontal nanowire transistors, vertical nanowire transistors, and the like.

The present disclosure proposes an efficient approach to leverage the advantages of advanced technology nodes, such as GAA transistors, to enhance the computing power and reduce power consumption in the core circuits used for driving compute-intensive applications, such as those involving artificial intelligence (AI), machine learning (ML), deep learning, big data, and the like. The GAA transistors are promising candidates for core circuits due to their high speed, low power consumption, low operating voltage and reduced device size. However, research has shown that significant manufacturing challenges will be faced in the integration of core circuits and non-core circuits including only GAA transistors on a same semiconductor wafer. The integration difficulties arise due to different voltage requirements for core and non-core circuits, in which the non-core circuits include peripheral circuits, I/O circuits, power-delivery circuits, memory circuits and the like, and are devised to operate under voltage greater than the core circuits do. As a result, gate dielectric layers in the GAA transistor of non-core circuits should be thicker than those in GAA transistors of core circuits in order to sustain higher operating voltages for the non-core circuits' GAA transistors. However, as will be detailed below, the thicker gate dielectric layer may be incompatible with the manufacturing specifications of current GAA transistors. Narrow gaps between adjacent nanosheets or adjacent nanowires in the GAA transistors cannot leave sufficient space for formation of the thicker gate dielectric layer and other electrode gate layers. As a result, the GAA transistor is not easily modified to meet the higher voltage requirements of the non-core circuits.

The present disclosure provides a semiconductor structure or a semiconductor device including a core circuit formed of GAA transistors that is manufactured by assigning different process nodes to core and non-core circuits. For example, the core circuit is designed and manufactured with the advanced technology node, i.e., the GAA transistors, while the non-core circuit is designed and manufactured with an earlier, or matured, technology node. For example, nGAA transistors are formed of planar-type or fin-type transistors. The GAA transistors and the nGAA transistors are formed separately in respective semiconductor wafers. Multiple advantages can be obtained when the core and non-core circuits are designed on different semiconductor wafers. For example, conventional semiconductor intellectual property (IP) designated for the non-core circuits, which involves compatible manufacturing processes in respect to matured technology nodes, can be used in HPC application as far as the core circuits and respective IP are separated therefrom and implemented on another semiconductor wafer. New IP design for non-core circuits to be integrated with the core circuit on one single wafer can be omitted to save production cost and resources can be directed to the design of the pure computing engine, i.e., the core circuit, which involves compatible manufacturing processes in respect to advanced technology nodes, on the respective semiconductor wafer dedicated for computing capability of the HPC. The semiconductor wafer with the core circuit that includes GAA transistors is bonded to the semiconductor wafer with the non-core circuit that includes the nGAA transistors. Accordingly, the semiconductor structure or the semiconductor device is obtained by dicing the bonded semiconductor wafers into individual dies and packaging the same into semiconductor chips. Each of the semiconductor chips includes a first substrate formed of GAA transistors in the core circuit and a second substrate formed of nGAA transistors in the non-core circuit, and the first substrate is bonded to the second substrate. Therefore, the core circuit can operate at full speed under the lowest power consumption, while the non-core circuit can operate under a higher working voltage without obstacles of integration with the core circuit. The most advanced processing element for the high-speed, high-performance computing processor, such as graphic processing unit (GPU) or central processing unit (CPU) for artificial intelligence (AI) machine learning or deep learning, can therefore be achieved in an efficient and economic manner.

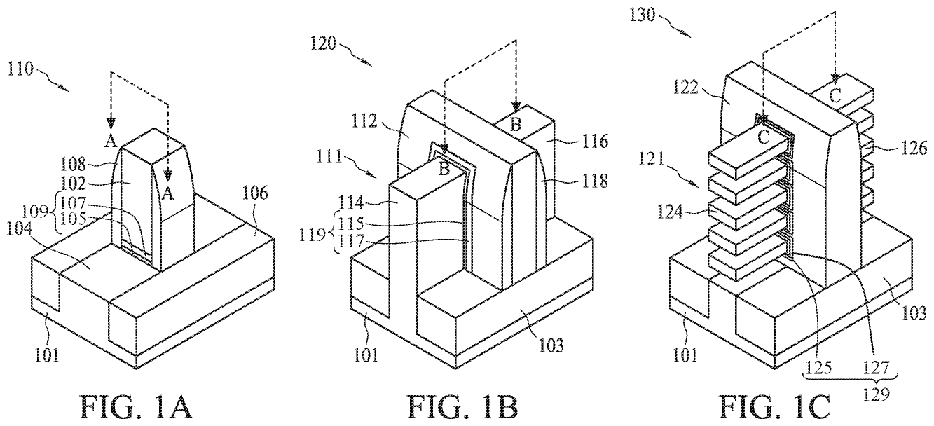

FIGS. 1A, 1B and 1C are perspective views of transistors 110, 120 and 130, respectively, of different transistor types, in accordance with some embodiments. The transistor 110 may be an nGAA transistor, e.g., a planar-type transistor. The transistor 120 may be another nGAA transistor, e.g., a fin-type transistor. The transistor 130 may be a GAA transistor. Throughout the present disclosure, the transistors 110 and 120, and other transistors not belonging to the type of GAA transistors are categorized as first-type (second-type) transistors, while the transistor 130 and other transistors belonging to the type of GAA transistors are categorized as a second-type (first-type) transistors. The transistor 110 in FIG. 1A is shown as a metal-oxide semiconductor (MOS) field-effect transistor (FET). However, the present disclosure is not limited thereto. The transistor 110 may also be expressed as a bipolar junction transistor or another type of nGAA transistor.

Referring to FIG. 1A, the transistor 110 includes a substrate 101, a gate structure 102, a source region 104, a drain region 106, a pair of gate spacers 108, and a gate dielectric layer 109. Some features of the transistor 110, such as an isolation region, a lightly-doped drain (LDD) region, a gate contact, a source contact, a drain contact, a contact etch-stop layer, an interlayer dielectric (ILD) layer, and the like, may be omitted from FIG. 1A for clarity and simplicity.

The gate structure 102, the source region 104 and the drain region 106 may be electrically coupled to respective voltage sources through the gate contact, the source contact and the drain contact (not separately shown), respectively, for switching on and switching off a channel current that flows in a channel region (not separately shown) directly under the gate dielectric layer 109 near an upper portion of the substrate 101 between the source region 104 and the drain region 106. In some embodiments, the gate dielectric layer 109 is formed of a dielectric material, such as silicon oxide or another suitable dielectric material. The gate dielectric layer 109 serves to electrically isolate the gate structure 102 from the substrate 101 and the channel region so that carriers may be drawn by an electric field generated by the gate structure 102 and the carriers may flow within the channel region. The gate structure 102 and the gate dielectric layer 109 are formed over the substrate 101, which has a planar upper surface, and the channel region is formed within the substrate 101. Thus, the transistor 110 is referred to as a planar-type transistor.

The material and a thickness of the gate dielectric layer 109 play an important role in ensuring proper functioning of the transistor 110. The thickness of the gate dielectric layer 109 and its dielectric constant are carefully selected with an aim to optimize a balance between the electric field generated by the gate structure 102 and the integrity of the gate dielectric layer 109 so that a breakdown voltage of the gate dielectric layer 109 can be tuned to an appropriate range. In some embodiments, the thickness of the gate dielectric layer 109 is further based on an operating voltage of the transistor 110, i.e., the voltage applied to the gate structure 102, the source region 104 and/or the drain region 106. The gate dielectric layer 109 is associated with nGAA transistors 110, 120 in the substrate 101. In some embodiments, the gate dielectric layer 109 includes at least two layers: one can be a gate silicon oxide layer 105, or so-called an interfacial layer, directly in contact with the surface of the substrate 101, another can be a high-k dielectric layer 107 stacked over the gate silicon oxide layer 105. The gate silicon oxide layer 105 is formed by thermal growth procedures under a temperature more than 1000° C., while the high-k dielectric layer 107, such as HfO₂ or ZrO₂, is formed by suitable deposition techniques such as chemical vapor deposition (CVD), atomic layer deposition (ALD), molecular beam epitaxy (MBE), or the like, based on the precision level required.

In some embodiments, the thickness of the gate silicon oxide layer 105 is greater than about 1.8 nm. In some embodiments, the thickness of the high-k dielectric layer 107 is between about 8 nm and 20 nm.

Referring to FIG. 1B, the transistor 120 includes a substrate 101, a gate structure 112, an isolation region 103, a source region 114, a drain region 116, a pair of gate spacers 118, and a gate dielectric layer 119. The source region 114 and the drain region 116 are formed in a fin structure 115. In some embodiments, the fin structure 115 is etched at the locations of the source region 114 and the drain region 116, and epitaxial layers are formed over the fin structure 115 or over the substrate 101 on two sides of the gate structure 112. Some features of the transistor 120, e.g., a lightly-doped drain (LDD) region, a gate contact, a source contact, a drain contact, a contact etch-stop layer, an interlayer dielectric (ILD) layer, and the like are omitted from FIG. 1B for clarity and simplicity.

The gate structure 112, the source region 114 and the drain region 116 may be electrically coupled to respective voltage sources through the gate contact, the source contact and the drain contact (not separately shown), respectively, for switching on and switching off a channel current that flows in a channel region (not separately shown) in the fin structure 115 covered by the gate dielectric layer 119 and over the substrate 101 between the source region 114 and the drain region 116. In some embodiments, the gate dielectric layer 119 is formed of a dielectric material, such as silicon oxide or another suitable dielectric material. The gate dielectric layer 119 serves to electrically isolate the gate structure 112 from the channel region so that carriers may be drawn by an electric field generated by the gate structure 112 and the carriers may flow within the channel region. Since the fin-shaped fin structure 111 is used in the transistor 120 where the channel region is surrounded by the gate structure 112 on two lateral sides and the upper side of the fin structure 111, the transistor 120 is referred to as a fin-type transistor. A current control and an electric field distribution of the transistor 120 are superior to those of the transistor 110, and thus the transistor 120 can provide improved performance and reduced power consumption compared to those of the transistor 110.

The material and a thickness of the gate dielectric layer 119 play an important role in ensuring proper functioning of the transistor 120. The thickness of the gate dielectric layer 119 and its dielectric constant are carefully selected to optimize a balance between the electric field generated by the gate structure 112 and the integrity of the gate dielectric layer 119 so that a breakdown voltage of the gate dielectric layer 119 can be tuned to an appropriate range. In some embodiments, the thickness of the gate dielectric layer 119 is also based on an operating voltage of the transistor 120, i.e., the voltage applied to the gate structure 112, the source region 114 and/or the drain region 116. In some embodiments, the gate dielectric layer 119 includes at least two layers: one can be a gate silicon oxide layer 115, or so-called an interfacial layer, directly in contact with the fin structure 111, another can be a high-k dielectric layer 117 stacked over the gate silicon oxide layer 115. The gate silicon oxide layer 115 is formed by thermal growth procedures under a temperature more than 1000° C., while the high-k dielectric layer 117, such as HfO₂ or ZrO₂, is formed by suitable deposition techniques such as chemical vapor deposition (CVD), atomic layer deposition (ALD), molecular beam epitaxy (MBE), or the like, based on the precision level required.

In some embodiments, the thickness of the gate silicon oxide layer 115 is greater than about 1.5 nm. In some embodiments, the thickness of the gate silicon oxide layer 115 is less than that of the gate silicon oxide layer 105. In some embodiments, the thickness of the high-k dielectric layer 117 is between about 3 nm and 15 nm.

Referring to FIG. 1C, the transistor 130 includes a substrate 101, a gate structure 122, an isolation region 103, a plurality of source regions 124, a plurality of drain regions 126, and a gate dielectric layer 129. The source regions 124 and the drain regions 126 are formed on two sides of a plurality of nanosheet structures 121. In some embodiments, the nanosheet structure 121 is etched at the locations of the source regions 124 and the drain regions 126, and epitaxial layers are formed on two sides of the nanosheet structure 121. Some features of the transistor 130, such as a lightly-doped drain (LDD) region, a gate contact, a source contact, a drain contact, a contact etch-stop layer, an interlayer dielectric (ILD) layer, and the like, are omitted from FIG. 1C for clarity and simplicity.

The gate structure 122, the source regions 124 and the drain regions 126 may be electrically coupled to respective voltage sources through the gate contact, the source contact and the drain contact (not separately shown), respectively, for switching on and switching off a channel current that flows in a channel region (not separately shown) in the nanosheet structures 121 between the source region 124 and the drain region 126 covered by the gate dielectric layer 129. In some embodiments, the gate dielectric layer 129 is formed of a dielectric material, such as silicon oxide or another suitable dielectric material. The gate dielectric layer 129 serves to electrically isolate the gate structure 122 from the channel region so that carriers may be drawn by an electric field generated by the gate structure 122 and the carriers may flow within the channel region. Due to the use of the nanosheet structure 121 in the transistor 130, in which the channel region in the nanosheet structures 121 is surrounded on four sides by the gate structure 122, the transistor 130 is referred to as a gate-all-around (GAA) transistor. Other types of GAA transistors, such as nanowire transistors, are also within the contemplated scope of the GAA transistor. A current control and an electric field distribution of the transistor 130 are superior to those of the transistors 110 and 120, and thus the transistor 130 can provide improved performance and reduced power consumption compared to those of the transistors 110 and 120.

In some embodiments, the nGAA transistors 110, 120 operate under a first voltage, and the GAA transistors operate under a second voltage less than the first voltage.

The material and a thickness of the gate dielectric layer 129 play an important role in ensuring proper functioning of the transistor 130. The thickness of the gate dielectric layer 129 and its dielectric constant are carefully selected to optimize a balance between the electric field generated by the gate structure 122 and the integrity of the gate dielectric layer 129 so that a breakdown voltage of the gate dielectric layer 129 can be tuned to an appropriate range. In some embodiments, the thickness of the gate dielectric layer 129 is also based on the operating voltage of the transistor 130, i.e., the voltage applied to the gate structure 122. The gate dielectric layer 129 is associated with GAA transistors 130 in the substrate 101. In some embodiments, the gate dielectric layer 129 includes at least two layers: one can be a gate silicon oxide layer 125, or so-called an interfacial layer, directly in contact with the nanosheets, another can be a high-k dielectric layer 127 stacked over the gate silicon oxide layer 125. The gate silicon oxide layer 125 is formed by thermal growth procedures under a temperature more than 1000° C., while the high-k dielectric layer 127, such as HfO₂ or ZrO₂, is formed by suitable deposition techniques such as chemical vapor deposition (CVD), atomic layer deposition (ALD), molecular beam epitaxy (MBE), or the like, based on the precision level required.

In some embodiments, the thickness of the gate silicon oxide layer 125 is less than about 1.0 nm. In some embodiments, the thickness of the high-k dielectric layer 127 is between about 3 nm and 10 nm. In some embodiments, a first combined thickness of the gate silicon oxide layer 125 and the high-k dielectric layer 127 is less than a second combined thickness of the gate silicon oxide layer 115 and the high-k dielectric layer 117 in the transistor 120 or a third combined thickness of the gate silicon oxide layer 105 and the high-k dielectric layer 107 in the transistor 110 described above. In some embodiments, the first combined thickness is at least 20%, 40%, or 50% less than the second or third combined thicknesses.

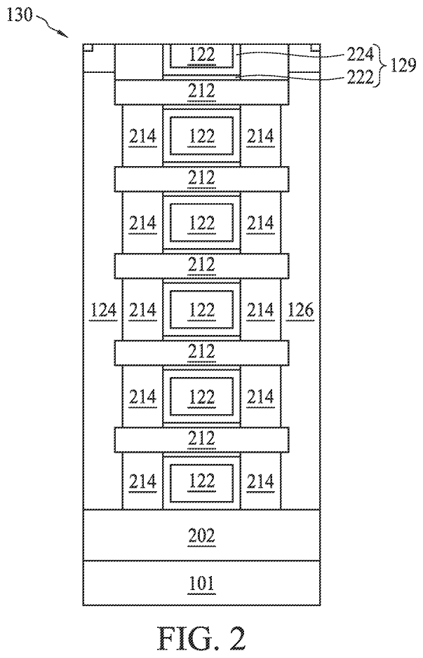

FIG. 2 is a schematic cross-sectional view along a sectional line CC of the transistor 130 shown in FIG. 1C, in accordance with some embodiments. Referring to FIG. 2, in addition to the substrate 101, the gate structure 122, the source region 124, the drain region 126 and the gate dielectric layer 129, the transistor 130 further includes a bottom dielectric layer 202, a plurality of channel regions 212, and a plurality of inner spacers 214. In some embodiments, the gate dielectric layer 129 includes an interfacial layer 222 and a high-k dielectric layer 224. In some embodiments, the gate structure 122 includes one or more metallic layers, e.g., one or more diffusion barrier layers, one or more capping layers, one or more work function adjustment layers, and a filling layer. Furthermore, the source region 124 is formed as a joined source region 124 for the individual channel regions 212, and the drain region 126 is formed as a joined drain region 126 for the individual channel regions 212.

Referring to FIGS. 1C and 2, in some embodiments, the gate structure 122 fills spaces between adjacent channel regions 212. In some embodiments, the gate dielectric layer 129 wraps around the channel region 212 and is arranged between the gate structure 122 and the channel region 212. Based on the above, it is clear that dimensions of the gate structure 122 and the gate dielectric layer 129 are constrained by the gaps between the adjacent channel regions 212. Further, in order to maintain desirable channel current control, the gate structure 122 needs to be formed with a sufficient thickness. As a result, the thickness of the gate dielectric layer 129 is constrained. Since the thickness of the gate dielectric layer 129 is closely related to the breakdown voltage and the operating voltage range of the transistor 130, the transistor 130 may be unsuitable for applications of relatively higher voltages. Some peripheral circuits, which do not serve as core circuits, operate under a voltage greater than voltages of core circuits. Thus, the thickness of the gate dielectric layer 129 may be limited to levels that are not adequate for non-core circuits, because semiconductor devices manufactured with insufficient thicknesses of the gate dielectric layer 129 may face reliability issues despite the GAA transistor structure.

Some efforts have been made to manufacture both the GAA transistors and the nGAA transistors on a same semiconductor wafer for implementing the core circuit and the non-core circuit of a semiconductor device. However, as described above, since the specifications of the gate dielectric layers 129 for the core circuit and non-core circuit applications are significantly different from each other, it may be difficult for deposition equipment to deposit the gate dielectric layers 129 with substantively different deposition requirements of the core and non-core circuits. Generally speaking, a space in between channel regions of a GAA transistor in a non-core circuit is allocated for deposition of a gate dielectric layer and gate structures. In a comparable embodiment, in order to obtain different gate dielectric thicknesses in the GAA structures in the core and non-core circuits of a same wafer, additional steps are performed to selectively enlarge the space in between channel regions of a GAA transistor in the non-core circuit by etching or thinning adjacent nanosheet layers prior to the gate dielectric deposition operation. Such additional steps performed in the GAA transistor in the non-core circuit increase the manufacturing complexity and production cost, as well as lowering the production yield.

The present disclosure therefore proposes to resolve the deposition issues from a different perspective. Since non-core circuits are not involved in principal tasks of high-speed, high-volume computing operations, such non-core circuit can be manufactured with processes that are less advanced than that of the core circuit on one substrate or wafer, and then bonded to the core circuits manufactured with processes that are more advanced than that of the non-core circuit on another free-standing substrate or wafer, in order to form a semiconductor structure or a semiconductor device meeting current requirement. As a result, the semiconductor structure or device formed according to different advanced levels of processes, or so-called process nodes, is able to include core circuits in possession of high-speed, lower-power computing capability and peripheral non-core circuits capable of sustaining high operating voltages or currents. Therefore, the high-speed computing processor can be obtained without sacrificing reliability of the peripheral non-core circuit.

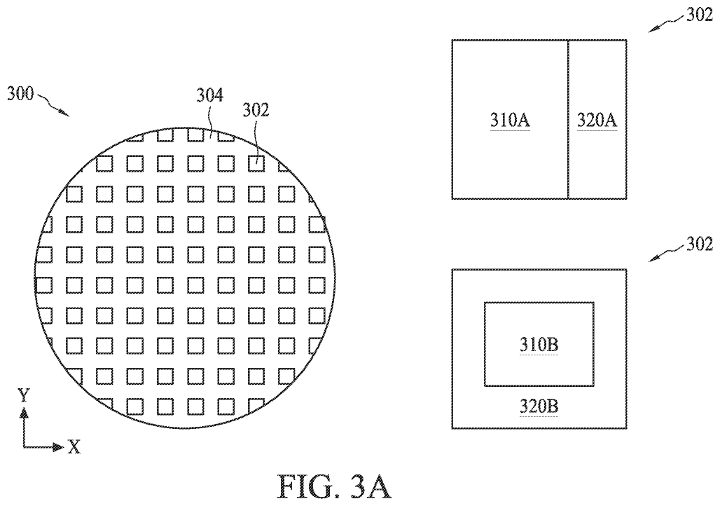

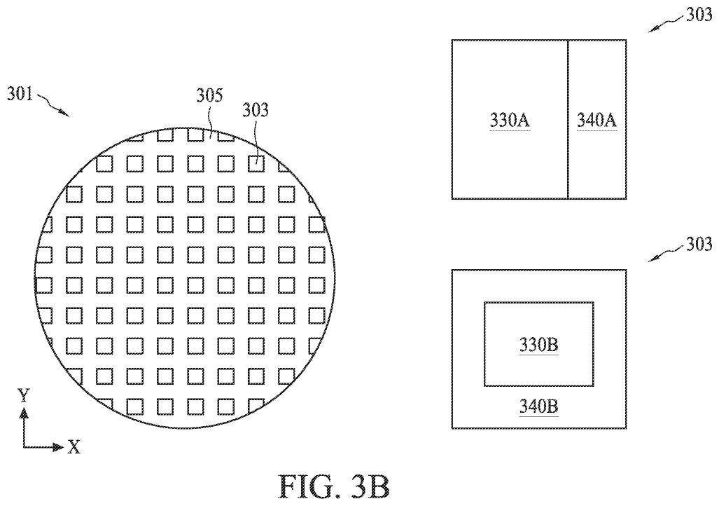

FIG. 3A is a schematic top view of a semiconductor wafer 300, which can be a periphery wafer with non-core circuits referred herein, in accordance with some embodiments of the present disclosure. The semiconductor wafer 300 includes a substrate. In some embodiments, the substrate includes a semiconductor material such as bulk silicon. In some embodiments, the substrate includes other semiconductor materials, such as silicon germanium, silicon carbide, gallium arsenide, or the like. In some embodiments, the substrate is a P-type semiconductive substrate (acceptor type). In some other embodiments, an N-type semiconductive substrate (donor type) is used. Alternatively, the substrate includes another elementary semiconductor, such as germanium; a compound semiconductor including gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or a combination thereof. In some embodiments, the substrate includes portions to form a semiconductor-on-insulator (SOI) substrate. In other embodiments, the substrate may include a doped epitaxial layer, a gradient semiconductor layer, and/or a semiconductor layer overlaying another semiconductor layer of a different type, such as a silicon layer on a silicon germanium layer.

In some embodiments, the semiconductor wafer 300 is partitioned into a plurality of device regions 302. The device regions 302 are separated and defined by a plurality of crossing scribe lines, which are also referred to as scribe regions 304. The device regions 302 may be arranged in an array with substantially equal areas from a top-view perspective. The scribe regions 304 may include parallel lines extending in an X direction and parallel lines extending in a Y direction perpendicular to the X direction, wherein the scribe areas 304 are used as the areas for separating the semiconductor wafer 300 into individual device regions 302.

In some embodiments, each of the device regions 302 includes a die region 310 and an interconnection area 320 adjacent to the die region 310. FIG. 3A shows two types of the device region 302 in which the die region 310 (including die regions 310A and 310B) and the interconnection area 320 (including interconnection areas 320A and 320B) are arranged differently. Referring to the upper right subfigure of FIG. 3A, the die region 310A and the interconnection area 320A are arranged side by side, that is, the die region 310A of the device region 302 and the interconnection area 320A of the same device region 302 share a lateral side. Referring to the lower right subfigure of FIG. 3A, the die region 310B is surrounded on four sides by the interconnection area 320B. In some embodiments, the four outer sides of the die region 310B contact four inner sides of the interconnection area 320B. In some embodiments, the interconnection area 320 is a part of an interconnection structure of the device region 302.

In some embodiments, some semiconductor devices or their components are formed on or in the substrate in the die region 310 of each of the device regions 302. For example, some conductive features, semiconductive features and dielectric features are formed or patterned on the substrate. Such components may form passive devices, such as resistors, capacitors, inductors, diodes, fuses, or the like, or active devices, such as field-effect transistors (FET), bipolar junction transistors (BJT), planar-type transistors, fin-type transistors, or the like. In some embodiments, the die region 310 includes non-core circuits, such as a peripheral circuit, an I/O circuit, an analog circuit, a power circuit, a memory circuit, or the like that associate with nGAA transistors.

FIG. 3B is a schematic top view of another semiconductor wafer 301, or a core wafer with core circuits referred herein, in accordance with some embodiments. The semiconductor wafer 301 includes a substrate similar to that of the semiconductor wafer 300. The semiconductor wafer 301 is similar to the semiconductor wafer 300 in many aspects, and descriptions of similar features are not repeated.

In some embodiments, the semiconductor wafer 301 is partitioned into a plurality of device areas (die regions) 303 by scribe regions 305. In some embodiments, each of the die regions 303 includes a die region 330 and an interconnection area 340 adjacent to the die region 330. FIG. 3B shows two types of the die region 303 in which the die region 330 (including die regions 330A and 330B) and the interconnection area 340 (including interconnection areas 340A and 340B) are arranged differently. Referring to the upper right subfigure of FIG. 3B, the die region 330A and the interconnection area 340A are arranged side by side, that is, the die region 330A and the interconnection area 340A of the same die region 303 share a lateral side. Referring to the lower right subfigure of FIG. 3B, the die region 330B is surrounded on four sides by the interconnection area 340B. In some embodiments, the four outer sides of the die region 330B contact four inner sides of the interconnection area 340B. In some embodiments, the interconnection area 340 is a part of an interconnection structure of the die region 303.

In some embodiments, some semiconductor devices or their components are formed on or in the substrate in the die region 330 of each of the die regions 303. For example, some conductive features, semiconductive features and dielectric features are formed or patterned on the substrate. Such components may form passive devices, such as resistors, capacitors, inductors, diodes, fuses, or the like, or active devices, such as field-effect transistors (FET), GAA transistors, nanosheet transistors, nanowire transistors, or the like. In some embodiments, the die region 330 includes core circuits that associate with GAA transistors.

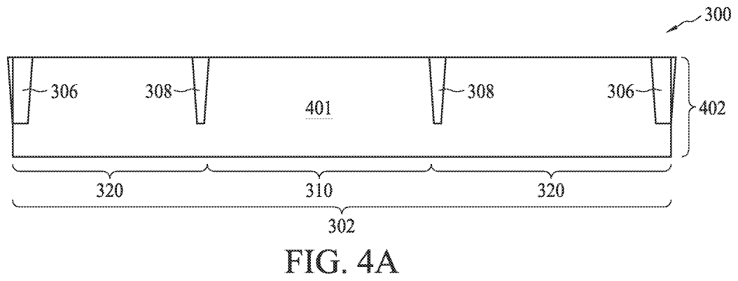

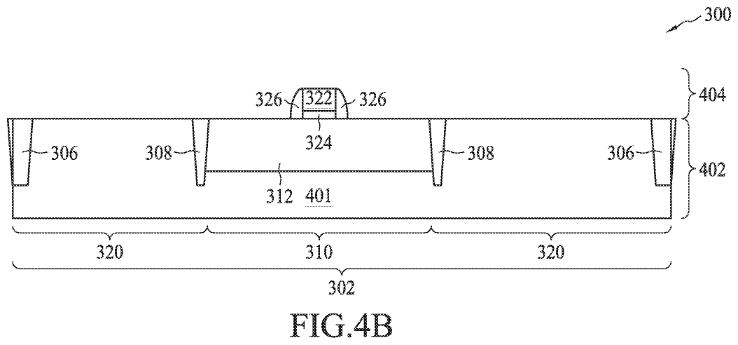

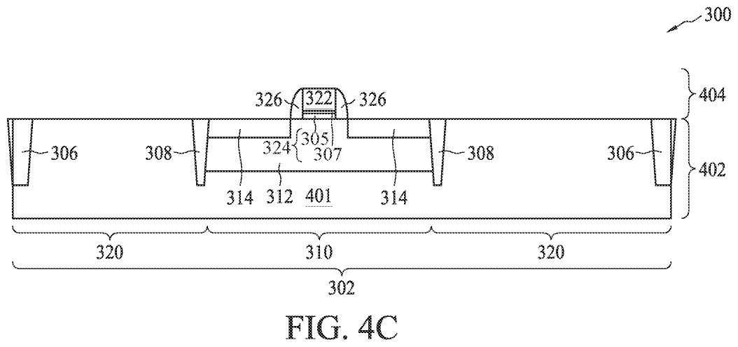

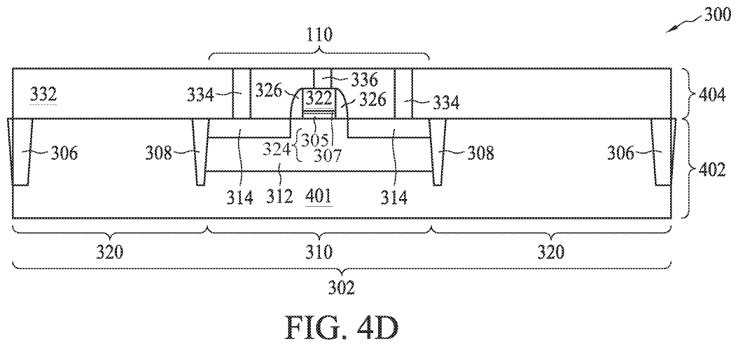

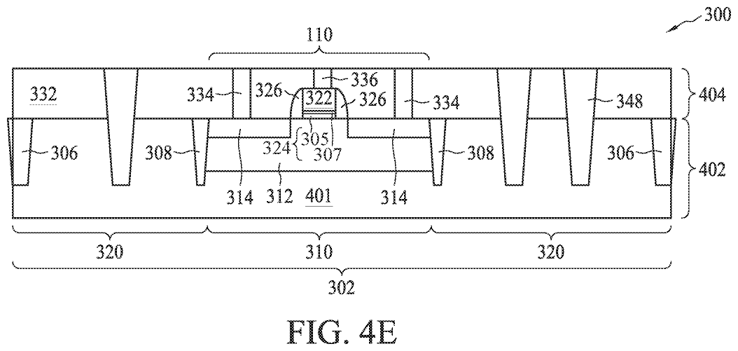

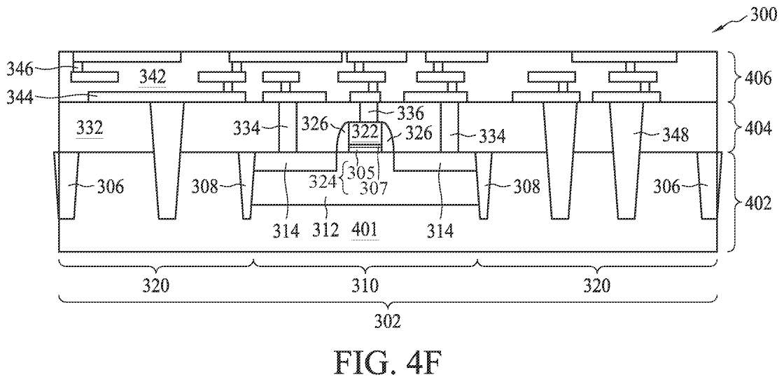

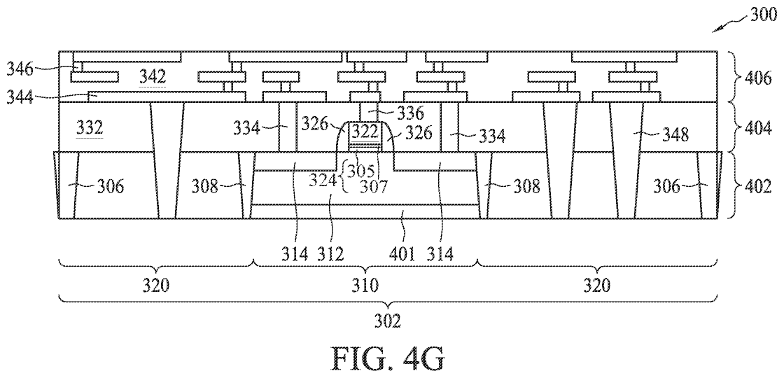

FIGS. 4A, 4B, 4C, 4D, 4E, 4F and 4G are schematic cross-sectional views of intermediate stages of a method of forming the semiconductor wafer 300, or the periphery wafer with non-core circuits referred herein, in accordance with some embodiments. The cross-sectional views of FIGS. 4A to 4G are taken along a sectional line AA of FIG. 1A. It should be understood that additional steps can be provided before, during, and after the stages shown in FIGS. 4A to 4G, and some of the steps described below can be replaced or eliminated in other embodiments of the method shown in FIGS. 4A to 4G. The order of the steps may be changed as needed for different embodiments of the present disclosure.

Referring to FIG. 4A, a blank semiconductor wafer 300 including a substrate layer 402 is provided or formed. The substrate layer 402 includes a semiconductor substrate 401 with a material similar to that of the substrate of the semiconductor wafer 300 illustrated with reference to FIG. 3A. Subsequently, a plurality of isolation regions 306 and 308 are formed on a surface of the semiconductor substrate 401. The isolation regions 306 and 308 may include dielectric materials, such as silicon oxide, silicon nitride, silicon oxynitride, silicon carbide, or the like. The isolation regions 306 and 308 are used to define and electrically separate a die region 310 and an interconnection area 320.

Referring to FIG. 4B, a well region 312 is formed close to the surface of the semiconductor substrate 401 within the die region 310. The well region 312 may be formed by an ion implantation operation. In some embodiments, the well region 312 may be doped with N-type dopants, such as phosphorus, arsenic, or the like, or doped with P-type dopants, such as boron, indium, or the like.

A gate layer 404 is formed over the substrate layer 402. First, a gate dielectric layer 324 is deposited on the surface of the semiconductor substrate 401. A gate structure 322 is subsequently formed over the gate dielectric layer 324. The formation of the gate structure 322 includes performing blanket deposition to form a dummy gate layer or a polysilicon gate layer over the gate dielectric layer 324 and performing a patterning operation to define dimensions of the gate structure 322 and the gate dielectric layer 324. In some embodiments, a pair of gate spacers 326 are formed on two sides of the gate structure 322. The gate dielectric layer 324 over the semiconductor substrate 401 is associated with nGAA transistors 110, 120 in the periphery wafer. In some embodiments, the gate dielectric layer 324 includes at least two layers, one can be a gate silicon oxide layer 305, or so-called an interfacial layer, directly in contact with the surface of the semiconductor substrate 401, another can be a high-k dielectric layer 307 stacked over the gate silicon oxide layer 305. The gate silicon oxide layer 305 is formed by thermal growth procedures under a temperature more than 1000° C., while the high-k dielectric layer 307 is formed by suitable deposition techniques such as chemical vapor deposition (CVD), atomic layer deposition (ALD), molecular beam epitaxy (MBE), or the like, based on the precision level required.

Referring to FIG. 4C, a source region 314 and a drain region 314 (collectively referred to as source/drain regions 314) are formed in the semiconductor substrate 401 on two sides of the gate spacers 326. The gate spacers 326 may serve as spacers between the gate structure 322 and the source region 314 or between the gate structure 322 and the drain region 314. The source/drain regions 314 may be formed by an ion implantation operation.

Referring to FIG. 4D, an interlayer dielectric (ILD) layer 332 is deposited over the substrate layer 402 and laterally surrounds the gate structure 322. Although not separately shown, a replacement gate process may be performed to remove the dummy gate layer and deposit a metallic gate electrode in place of the dummy gate layer. Further, a plurality of contacts, including a source contact 334 and a drain contact 334, are formed in the ILD layer 332 and are electrically coupled to corresponding source/drain regions 314. In some embodiments, a gate contact 336 is formed over the gate structure 322 and electrically coupled thereto. A planar-type transistor 110 is thus formed on the semiconductor wafer 300.

Referring to FIG. 4E, a plurality of through-substrate vias (TSVs) 348 are formed in the interconnection area 320 and extend through the gate layer 404 and into the substrate layer 402. The TSVs 348 are exposed at a surface of the gate layer 404. The TSVs 348 may include a material similar to a material of metal lines 344 or metal vias 346 in a redistribution layer 406 (shown in FIG. 4F). The TSVs 348 may be used to electrically couple the transistor 110 of the semiconductor wafer 300 to and from external circuits outside of the semiconductor structure or the semiconductor device.

Referring to FIG. 4F, a redistribution layer (RDL) 406 is formed over the gate layer 404. The RDL 406 may be considered part of an interconnect structure of a device region 302 (shown in FIG. 3A) of the semiconductor wafer 300. The RDL 406 is configured to electrically interconnect components of the gate layer 404, or electrically couple the components of the gate layer 404 to overlying layers of the semiconductor wafer 300 or to external circuits. The RDL 406 may include a plurality of metal line layers, wherein each of the metal line layers includes a plurality of conductive lines 344. The conductive lines 344 in each metal line layer extend along a horizontal direction and are interconnected through adjacent vertical conductive vias 346 or TSVs 348 in respective conductive via layers. The conductive lines 344 and the conductive vias 346 are formed of conductive materials, such as copper, tungsten, aluminum, silver, titanium, tantalum, combinations thereof, or the like. The conductive lines 344 and the conductive vias 346 may be electrically insulated by one or more inter-metal dielectric (IMD) layers 342. The IMD layer 342 may include a dielectric material, such as silicon oxide, silicon nitride, silicon carbide, silicon oxynitride, a polymeric material, or the like. Numbers and configurations of the metal line layers and the conductive via layers for the conductive lines 344 and the conductive vias 346 can be configured as required for different applications, and the present disclosure is not limited thereto.

Referring to FIGS. 3A and 4F, in some embodiments, the substrate layer 402 and the gate layer 404 include a plurality of device regions 302 on the first semiconductor wafer 300 (although FIG. 4F only shows one example device region 302), in which cach of the device regions 302 includes a die region 310 and one or more interconnection areas 320. Further, in some embodiments, the RDL 406 disposed over the plurality of device regions 302 forms the interconnection structure for the die region 310 in each of the plurality of device regions 302 together with the interconnection area 320. As described below, the interconnection structure is configured to transmit power or electrical signals between nGAA transistors 110, 120 in the periphery wafer and the GAA transistors 130 in the core wafer.

Referring to FIG. 4G, a backside of the substrate layer 402 is thinned to expose one end of the TSVs 348. The thinning may be performed by a chemical mechanical polishing (CMP) operation, mechanical grinding, or another suitable planarization operation. In some embodiments, bottom portions of the isolation regions 306 and 308 are exposed after the thinning operation.

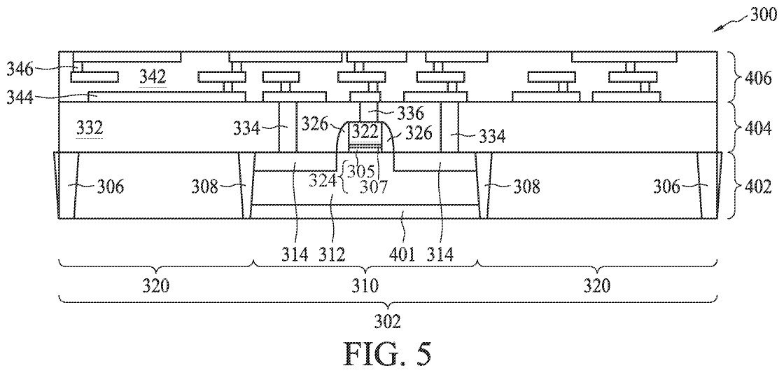

FIG. 5 is a schematic cross-sectional view of the semiconductor wafer 300 shown in FIG. 3A, in accordance with some embodiments. The semiconductor wafer 300 shown in FIG. 5 is similar to the semiconductor wafer 300 shown in FIG. 4G, and descriptions of similar features are not repeated. The semiconductor wafer 300 shown in FIG. 5 is different from the semiconductor wafer 300 shown in FIG. 4G mainly in that, in some embodiments referring but not limited to FIG. 5 of the present disclosure, the TSVs 348 are absent from the semiconductor wafer 300, or the periphery wafer, as depicted in FIG. 5.

It should be noted that the semiconductor wafer 300 shown in FIG. 4G and FIG. 5 are provided for illustrative purposes. Other examples of nGAA transistors can also fall within the contemplated scope of the present disclosure. For example, the fin-type transistor 120 or other nGAA transistors can be utilized in place of the planar-type transistor 110, and the present disclosure is not limited thereto.

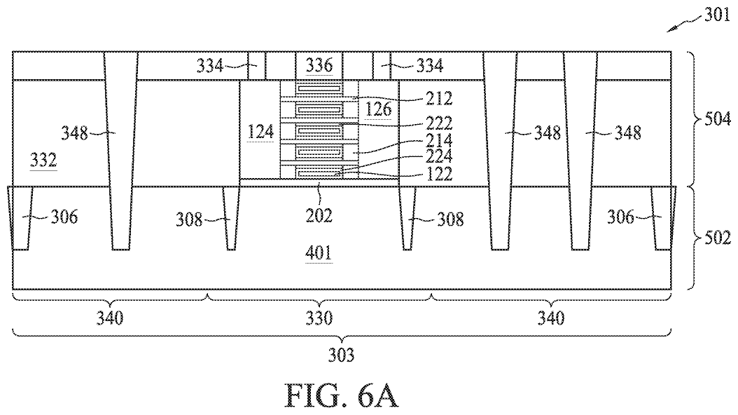

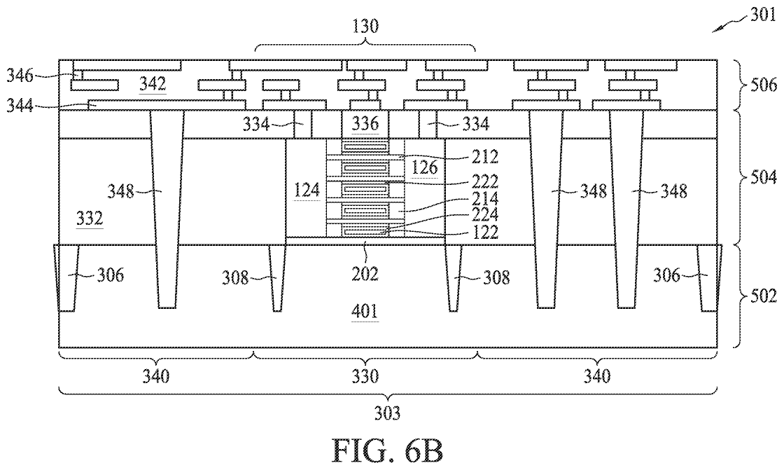

FIG. 6A is a schematic cross-sectional view of the semiconductor wafer 301, or the core wafer with core circuits referred herein, shown in FIG. 3B, in accordance with some other embodiments. The cross-sectional view of FIG. 6A is taken along a sectional line CC of FIG. 1C. The semiconductor wafer 301 shown in FIG. 6A is similar to the first semiconductor wafer 300, and descriptions of similar features are not repeated. The semiconductor wafer 301 is different from the semiconductor wafer 300 mainly in that the semiconductor wafer 301 includes a plurality of GAA transistors 130 instead of the planar-type transistors 110 or the fin-type transistors 120. As shown in FIG. 6A, the semiconductor wafer 301 includes a substrate layer 502 and a gate layer 504 over the substrate layer 502. Materials, configurations and formation methods of the substrate layer 502 and the gate layer 504 are similar to those of the substrate layer 402 and the gate layer 404, respectively. The GAA transistors 130 are formed in the gate layer 504 and include a bottom dielectric layer 202, a plurality of channel regions 212, and a plurality of inner spacers 214. In some embodiments, as shown in FIG. 2, a gate dielectric layer 129 includes an interfacial layer 222 and a high-k dielectric layer 224. In some embodiments, a gate structure 122 includes one or more metallic layers, such as one or more diffusion barrier layers, one or more capping layers, one or more work function adjustment layers, and a filling layer. Furthermore, a source region 124 is formed as a joined source region 124 for the individual channel regions 212, and a drain region 126 is formed as a joined drain region 126 for the individual channel regions 212. As a result, the GAA transistors 130 are formed on the semiconductor wafer 301.

FIG. 6B is a schematic cross-sectional view of the semiconductor wafer 301 shown in FIG. 3B, in accordance with some embodiments of the present disclosure. The semiconductor wafer 301 shown in FIG. 6B is similar to the semiconductor wafer 301 shown in FIG. 6A, and descriptions of similar features are not repeated. The semiconductor wafer 301 shown in FIG. 6B is different from the semiconductor wafer 301 shown in FIG. 6A mainly in that the semiconductor wafer 301 shown in FIG. 6B further includes an RDL 506 or an interconnection structure over the gate layer 504. Materials, configurations and formation methods of the RDL 506 are similar to those of the RDL 406. The RDL 506 is electrically connected to a GAA transistor 130 through source/drain contacts 334 or a gate contact 336 disposed in the portion of gate layer 504 over the GAA transistor 130.

Referring to FIGS. 3B and 6B, in some embodiments, the substrate layer 502 and the gate layer 504 include a plurality of device regions 303 on the semiconductor wafer 301, in which each of the device regions 303 includes a die region 330 and one or more interconnection areas 340. Further, in some embodiments, the RDL 506 disposed over the plurality of device regions 303 forms an interconnection structure for each die region 330 in the plurality of device regions 303. As described below, the interconnection structure is configured to transmit power or electrical signals between nGAA transistors 110, 120 in the periphery wafer and the GAA transistors 130 in the core wafer.

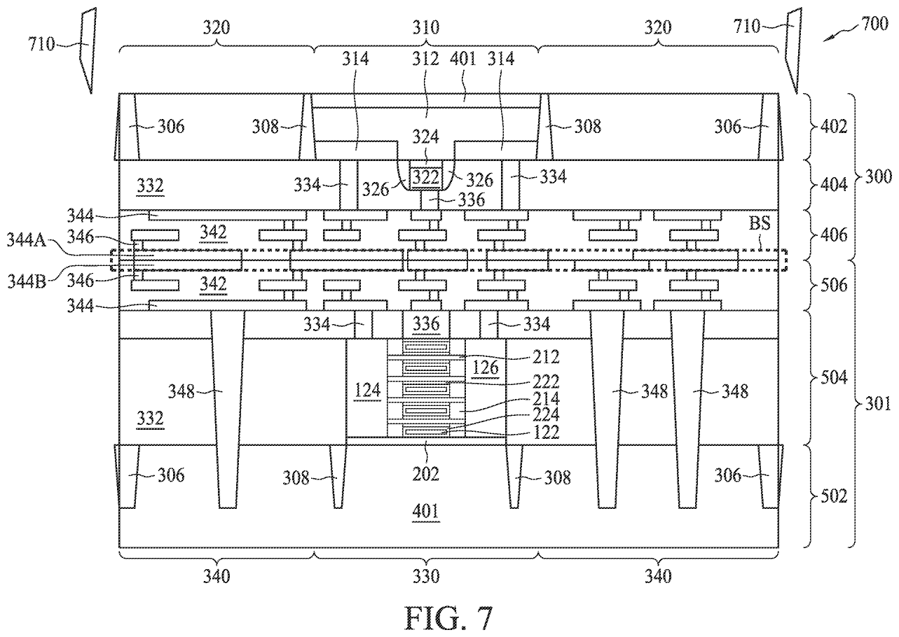

FIG. 7 is a schematic cross-sectional view of a semiconductor structure 700, in accordance with some embodiments. Note the semiconductor structure may be called a semiconductor device interchangeably herein. The semiconductor structure 700 is formed by bonding the semiconductor wafer 300, or the periphery wafer, to the semiconductor wafer 301, or the core wafer. Each of the die regions 310 on the semiconductor wafer 300 is electrically coupled to a corresponding one of the die regions 330 on the semiconductor wafer 301. In some embodiments, prior to the bonding operation, each of the die regions 310 on the semiconductor wafer 300 is vertically aligned with a corresponding die regions 330 on the semiconductor wafer 301. Similarly, each of the interconnection areas 320 on the semiconductor wafer 300 is vertically aligned with a corresponding interconnection areas 340 on the semiconductor wafer 301

The RDL 406 of the semiconductor wafer 300 is bonded to the RDL 506 of the semiconductor wafer 301. A bonding structure BS is formed by parts of the RDL 406 and RDL 506 to bond the semiconductor wafer 300 and the semiconductor wafer 301. For example, a topmost metal line layer of the RDL 506 and a bottommost metal line layer of the RDL 406 form the bonding structure BS of the semiconductor structure 700. As described below, the bonding structure BS is configured to supply power or transmit electrical signals to the GAA transistors 130 through the nGAA transistors 110, 120.

In some embodiments, the bonding structure BS can be a hybrid bonding layer, in which the exposed bond pads 344A and dielectric surface over the RDL 406 are bonded to the corresponding bond pads 344B and dielectric surface over the RDL 506. In some embodiments, the semiconductor structure 700 is formed by a front-to-front bonding, in which the front side of the semiconductor wafer 300 faces the front side of the semiconductor wafer 301.

In some embodiments, the semiconductor structure 700 in its wafer form is subsequently diced or separated into individual semiconductor structures. A dicing tool 710 may be utilized to perform the dicing operation. The dicing tool 710 may include a dicing laser, a dicing blade, or the like.

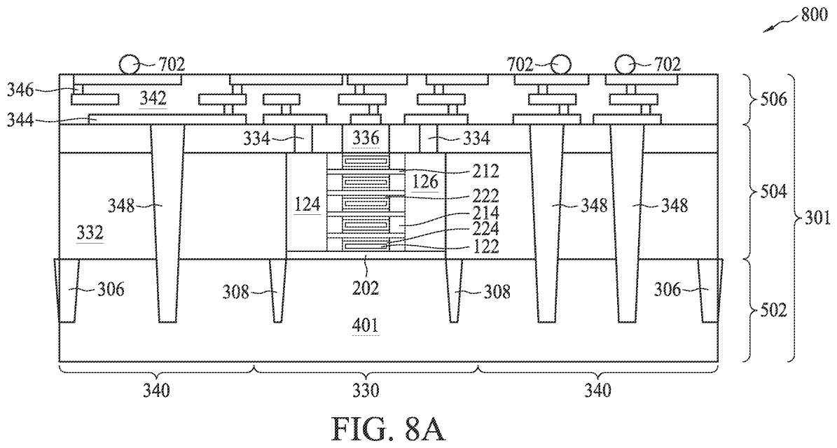

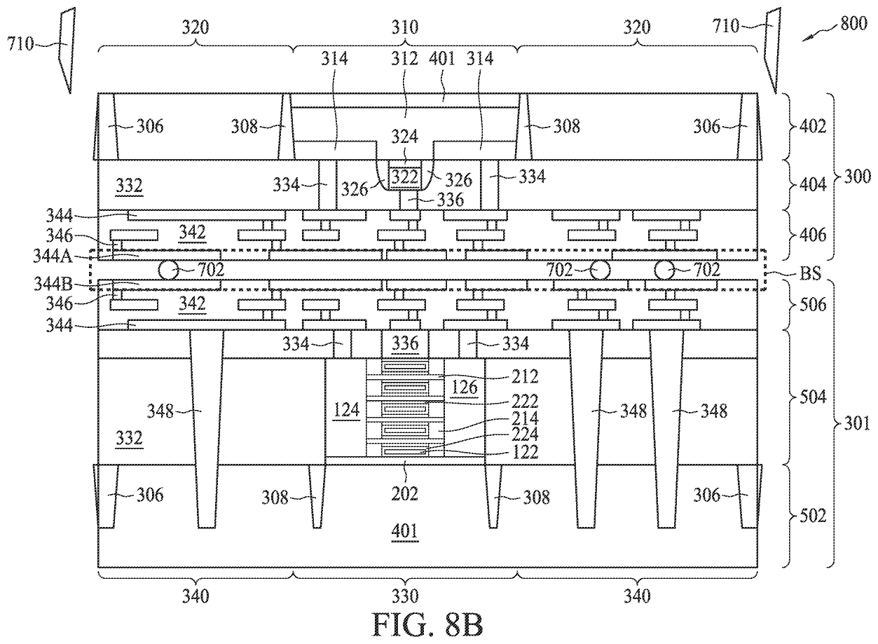

FIGS. 8A and 8B are schematic cross-sectional views of intermediate stages of a method of bonding the semiconductor wafer 300 to the semiconductor wafer 301, in accordance with some embodiments of the present disclosure. Referring to FIG. 8A, a plurality of connectors 702 are formed over the RDL 506 of the semiconductor wafer 301. The connectors 702 are configured to electrically connect the RDL 506 to the RDL 406 of the semiconductor wafer 300 depicted in FIG. 8B. The connectors 702 may include conductive materials, such as conductive bumps, micro bumps, ball grid array bumps, controlled collapse chip connection (C4) bumps, or the like. The connectors 702 may include a solder connection or soft metal material. In some embodiments, the solder connection includes a material such as tin (Sn), lead (Pb), nickel (Ni), gold (Au), silver (Ag), copper (Cu), bismuthinite (Bi), a combination thereof, or a mixture of other electrically conductive materials. In one embodiment, the solder material is a lead-free material.

Referring to FIG. 8B, the semiconductor wafer 300 is bonded to the semiconductor wafer 301 through the connectors 702. A flip-chip bonding operation can be performed, in which a front side of the semiconductor wafer 300 is flipped and bonded to the semiconductor wafer 301. A bonding structure BS is formed by parts of the RDL 406, the connectors 702, and the RDL 506. For example, the under bump metallization (UBM) 344A of the RDL 406 are bonded to the under bump metallization (UBM) 344B of the RDL 506 through the connectors 702. As described below, the bonding structure BS is configured to supply power or transmit electrical signals to the GAA transistors 130 in the core wafer through the nGAA transistors 110, 120 in the periphery wafer. In some embodiments, the semiconductor structure 800 is formed by a front-to-front bonding, in which the front side of the semiconductor wafer 300 faces the front side of the semiconductor wafer 301.

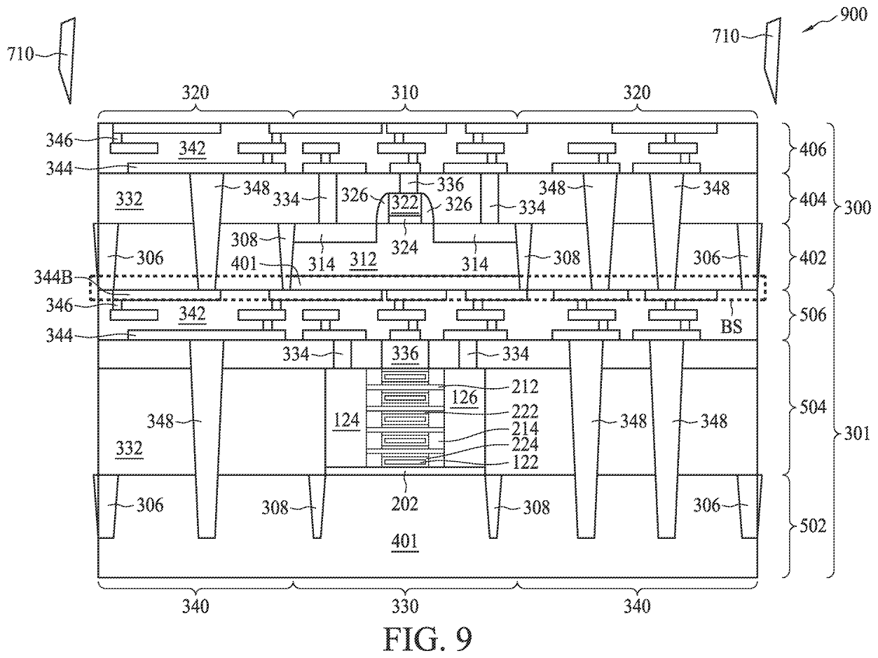

FIG. 9 is a schematic cross-sectional view of a semiconductor structure 900, in accordance with some embodiments of the present disclosure. The semiconductor structure 900 is similar to the semiconductor structure 700, and descriptions of similar features are not repeated. The semiconductor structure 900 is different from the semiconductor structure 700 mainly in that the semiconductor structure 900 is formed by a front-to-back bonding, in which the front side of the semiconductor wafer 301 faces the back side of the semiconductor wafer 300. In some embodiments, the bonding structure BS can be a hybrid bonding layer, in which the bond pads 344B and dielectric surface over the RDL 506 are in connection to the corresponding bond pads and dielectric surface of a back side RDL (not illustrated) on a back side of the semiconductor wafer 300 The back side RDL of the semiconductor wafer 300 can be in direct electrical coupling to the TSVs 348 of the semiconductor wafer 300.

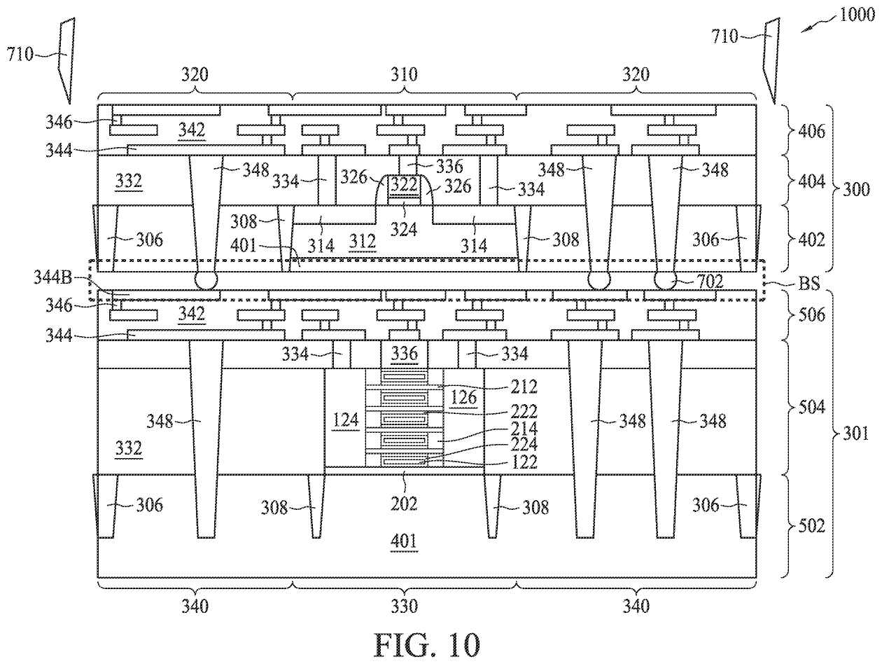

FIG. 10 is a schematic cross-sectional view of a semiconductor structure 1000, in accordance with some embodiments of the present disclosure. The semiconductor structure 1000 is similar to the semiconductor structure 800, and descriptions of similar features are not repeated. The semiconductor structure 1000 is different from the semiconductor structure 800 mainly in that the semiconductor structure 1000 is formed by a front-to-back bonding, in which the front side of the semiconductor wafer 301 faces the back side of the semiconductor wafer 300. In some embodiments, the bonding is performed by forming the connectors 702 on the under bump metallization (UBM) 344B of the RDL 506 and electrically connecting to under bump metallization (UBM) on a back side RDL (not illustrated) that is disposed at the back side of the semiconductor wafer 300.

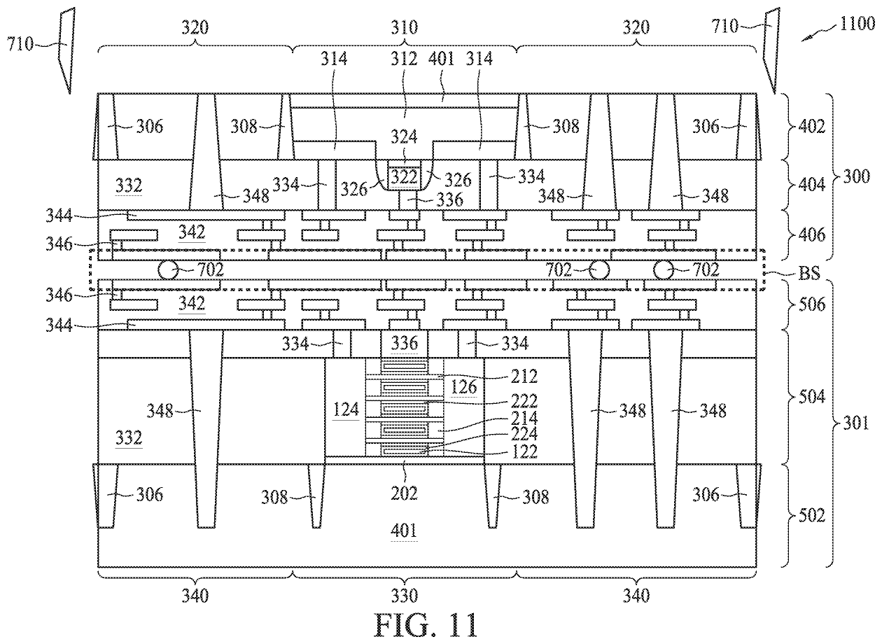

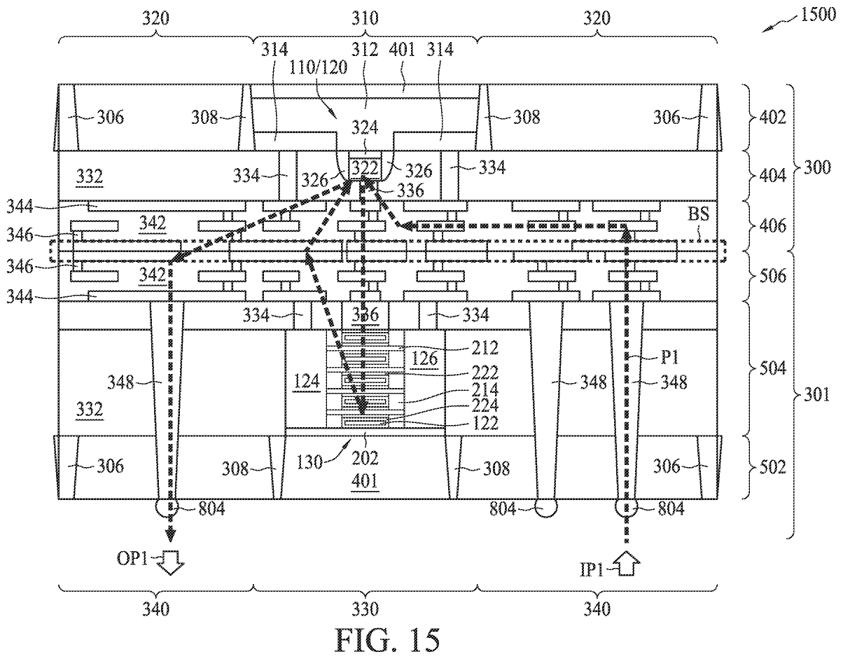

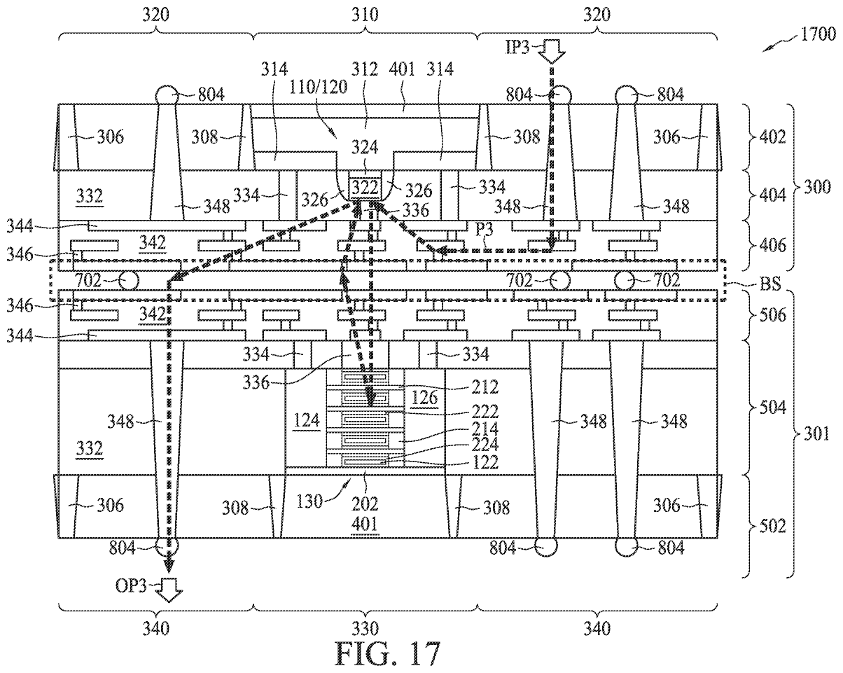

FIG. 11 is a schematic cross-sectional view of a semiconductor structure 1100, in accordance with some embodiments of the present disclosure. The semiconductor structure 1100 is similar to the semiconductor structure 800 shown in FIG. 8B, and descriptions of similar features are not repeated. The semiconductor structure 1100 is different from the semiconductor structure 800 mainly in that the semiconductor wafer 300 further includes TSVs 348 formed in the interconnection area 320 and electrically coupled to the RDL 406. Different applications of the semiconductor structures 800 and 1100 are described in FIG. 15 and FIG. 17, respectively, of the present disclosure.

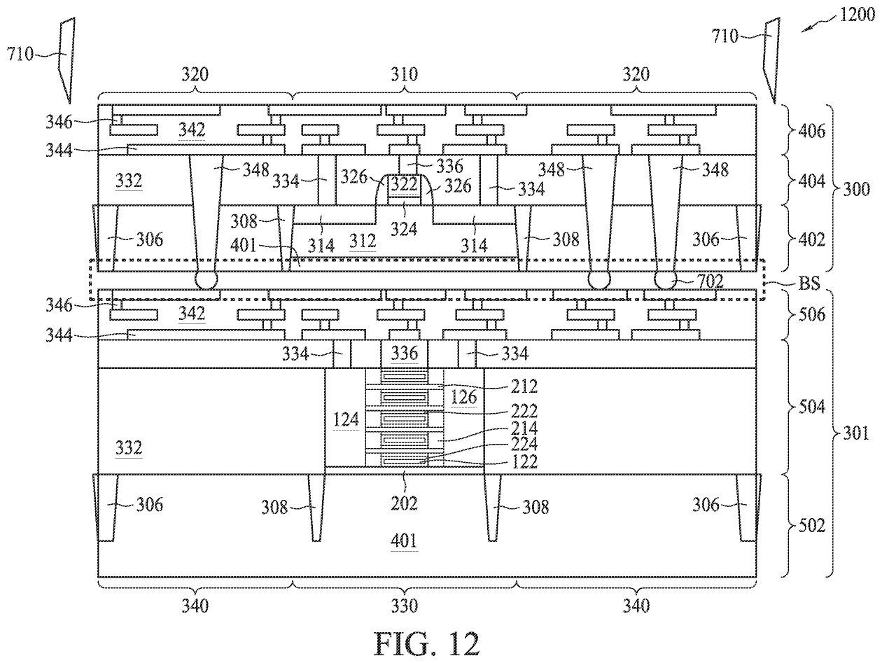

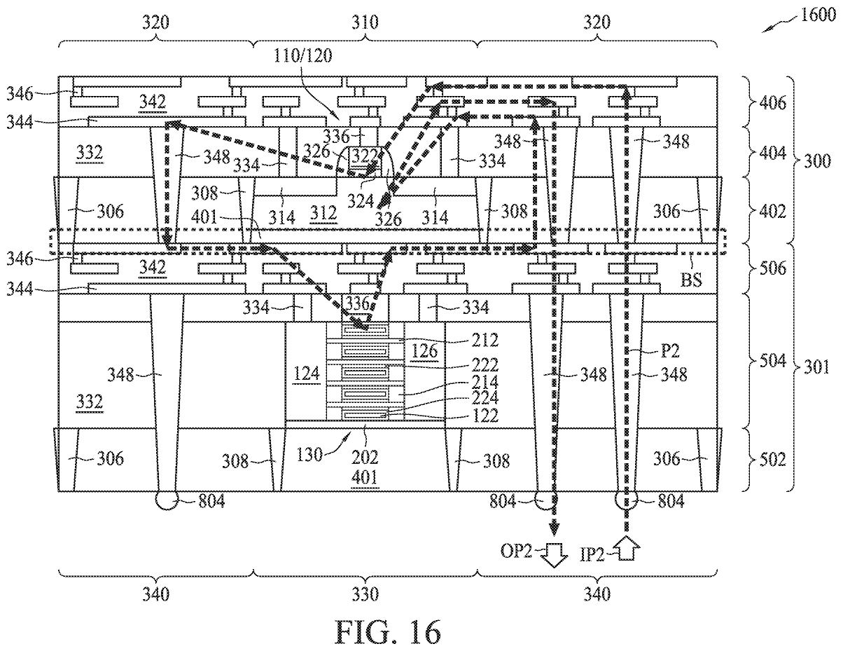

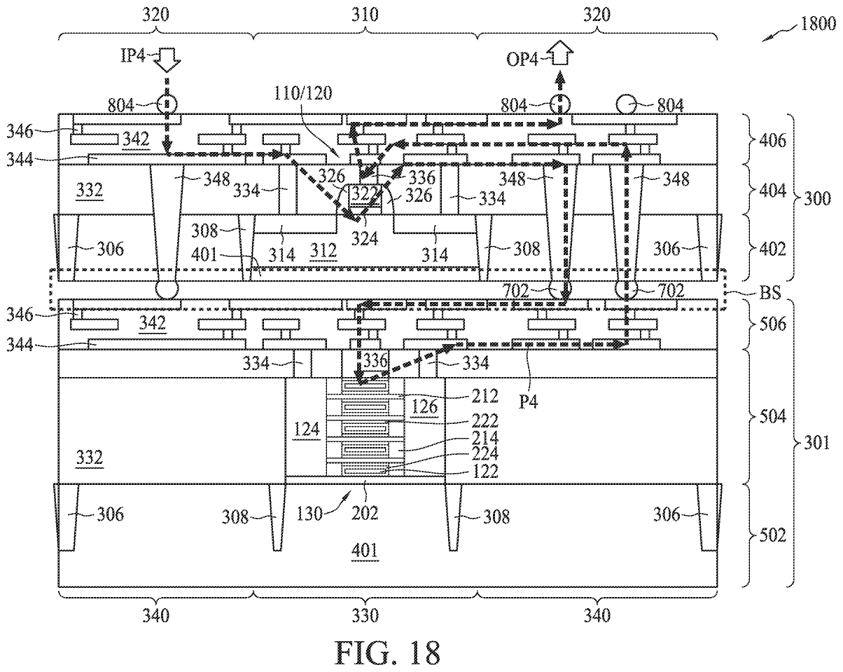

FIG. 12 is a schematic cross-sectional view of a semiconductor structure 1200, in accordance with some embodiments of the present disclosure. The semiconductor structure 1200 is similar to the semiconductor structure 1000 shown in FIG. 10, and descriptions of similar features are not repeated. The semiconductor structure 1200 is different from the semiconductor structure 1000 mainly in that the TSVs 348 of the semiconductor wafer 301 are omitted. Different applications of the semiconductor structure 1000 and 1200 are described in FIG. 16 and FIG. 18, respectively, of the present disclosure.

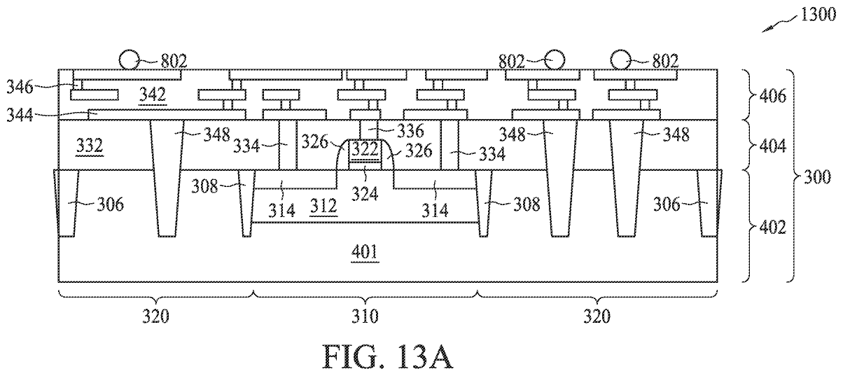

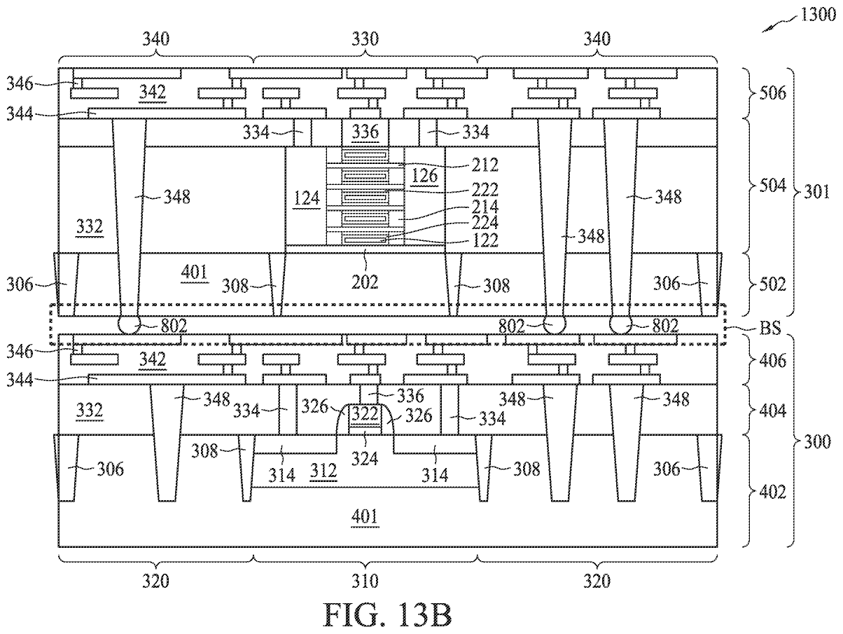

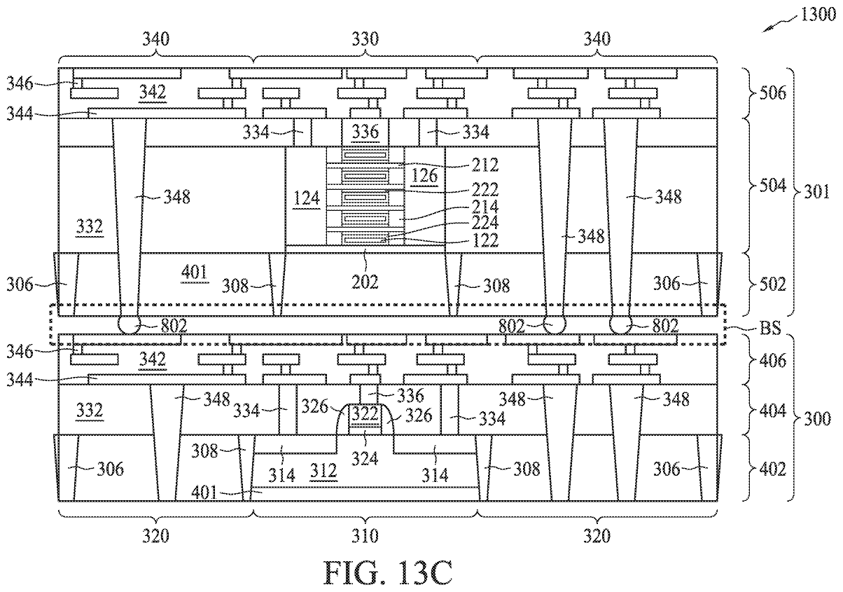

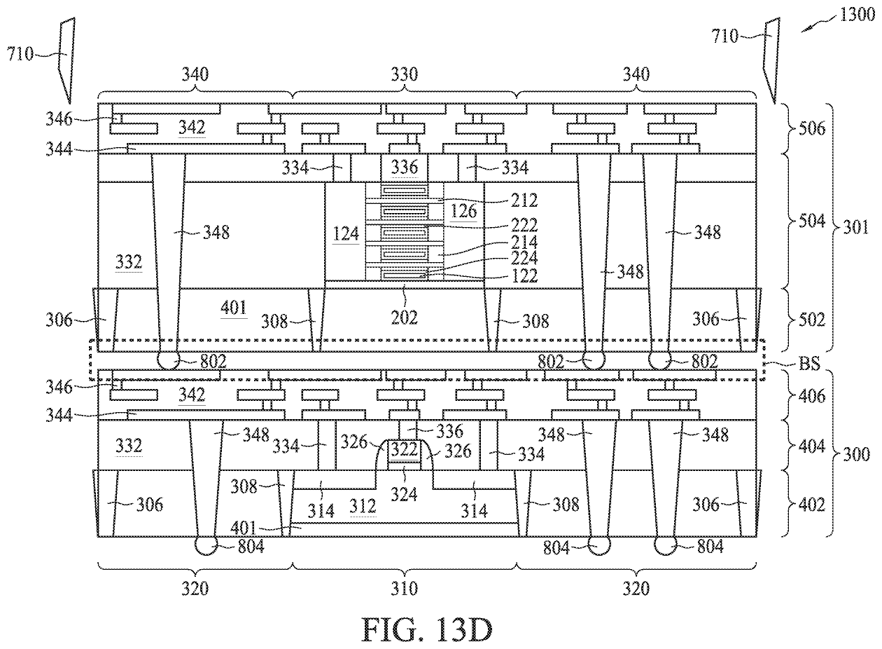

FIGS. 13A, 13B, 13C and 13D are schematic cross-sectional views of intermediate stages of a method of bonding the semiconductor wafer 301 to the semiconductor wafer 300 to form a semiconductor structure 1300, in accordance with some embodiments of the present disclosure. Referring to FIG. 13A, a plurality of connectors 802 are formed over the RDL 406 of the semiconductor wafer 300. The connectors 802 are configured to transmit electrical signals between the semiconductor wafer 300 and the semiconductor wafer 301 depicted in FIG. 13B. For example, the connectors 802 are in connection with an under bump metallization (UBM) of a back side RDL (not illustrated) disposed at the back side of the semiconductor wafer 301. The connectors 802 may include conductive materials, such as conductive bumps, micro bumps, ball grid array bumps, C4 bumps, or the like. The materials and configurations of the connectors 802 are similar to those of the connectors 702. The semiconductor structure 1300 is formed by a front-to-back bonding, in which the front side of the semiconductor wafer 300 faces the back side of the semiconductor wafer 301.

Referring to FIG. 13C, the back side of the semiconductor wafer 300 is thinned until an end of the TSV 348 is exposed. The thinning operation may be performed using CMP, mechanical grinding, or other suitable planarization methods. For example, a bottom end of the TSV 348 in the semiconductor wafer 300 is exposed by the thinning operation. The exposed end of the TSV 348 can further connect to external signal or power.

Referring to FIG. 13D, a plurality of connectors 804 are disposed at the exposed end of the TSV 348 in the semiconductor wafer 300. The connectors 804 are configured to electrically connect the semiconductor structure 1300 to external circuits. The connectors 804 may include conductive materials, such as conductive bumps, micro bumps, ball grid array bumps, C4 bumps, or the like. The materials and configurations of the connectors 804 are similar to those of the connectors 702 or 802. In some embodiments, the semiconductor structure 1300 is formed by a front-to-back bonding, in which the front side of the semiconductor wafer 300 faces the back side of the semiconductor wafer 301.

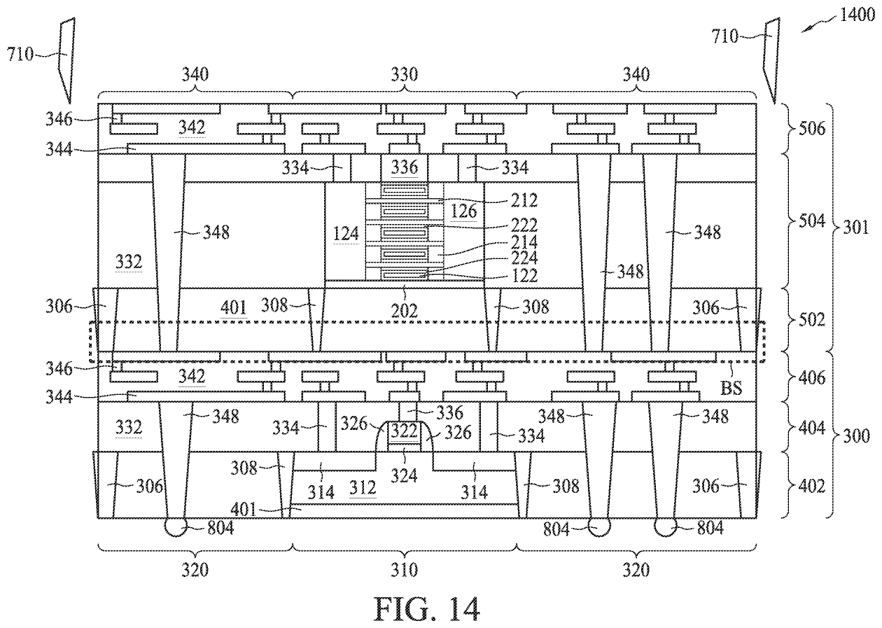

FIG. 14 is a schematic cross-sectional view of a semiconductor structure 1400, in accordance with some embodiments of the present disclosure. The semiconductor structure 1400 is similar to the semiconductor structure 1300 shown in FIG. 13, and descriptions of similar features are not repeated. The semiconductor structure 1400 is different from the semiconductor structure 1300 mainly in that the semiconductor wafer 300 and the semiconductor wafer 301 in FIG. 14 are bonded by a hybrid bonding structure.

In some embodiments, a bonding structure BS is formed by parts of the RDL 406 of the semiconductor wafer 300 and a back side RDL (not illustrated) of the semiconductor wafer 301. For example, a hybrid bonding interface of the RDL 406 of the semiconductor wafer 300 can be brought in contact with a corresponding hybrid bonding interface of the back side RDL (not illustrated) of the semiconductor wafer 301. The back side RDL (not illustrated) of the semiconductor wafer 301 is at least electrically coupled to the TSVs 348 in the semiconductor wafer 301.

FIG. 15 is a schematic diagram showing a transmission path P1 of power and/or signals of a semiconductor structure 1500, in accordance with some embodiments of the present disclosure. Note the semiconductor structure may be called a semiconductor device interchangeably herein. The semiconductor structure 1500 may be electrically coupled to external power source/ground or signal source/signal sink to communicate power or electrical signals.

The transmission path P1 is used to represent how power is electrically connected between a power source (external to the semiconductor structure 1500) and a ground terminal (external to the semiconductor structure 1500), or how an electrical signal is transmitted between a signal source (external to the semiconductor structure 1500) and a signal sink (external to the semiconductor structure 1500). In some embodiments, the non-core circuit in the periphery substrate, i.e., the diced version of the semiconductor wafer 300 previously described, is configured to serve as an interface circuit between an external circuit (e.g., a power/ground network or a signal network) and the core circuit in the core substrate, i.e., the diced version of the semiconductor wafer 301 previously described. Thus, the power or electrical signal from the external circuit can be transmitted to the core circuit in the core substrate through the non-core circuit in the periphery substrate. Similarly, the power or electrical signals outputted from the core circuit in the core substrate can be transmitted to the external circuit through the non-core circuit in the periphery substrate.

Referring to FIG. 15, for example, in an inbound direction, the transmission path P1 covers a route from an input terminal IP1 such as a connector 804 in the interconnection area 340 of the semiconductor wafer 301, to a TSV 348 in the interconnection area 340 of the semiconductor wafer 301, the RDL 506, the bonding structure BS, the RDL 406, the nGAA transistor 110 or 120 in the die region 310 of the semiconductor wafer 300, the RDL 406, the bonding structure BS and the RDL 506, to the GAA transistor 130 in the die region 330 of the semiconductor wafer 301. In the inbound direction depicted for transmission path P1 in FIG. 15, the signal or power passes the bonding structure BS twice before it reaches the core circuit, i.e., the GAA transistor 130 in the core wafer.

In an outbound direction, the transmission path P1 covers a route from the GAA transistor 130 in the die region 330 of the semiconductor wafer 30, to the RDL 506, the bonding structure BS, the RDL 406, the nGAA transistor 110 or 120 in the die region 310 of the semiconductor wafer 300, the RDL 406, the bonding structure BS, the RDL 506, and a TSV 348 in the interconnection area 340 of the semiconductor wafer 301, to an output terminal OP1 such as a connector 804 in the interconnection area 340 of the semiconductor wafer 301. In the outbound direction depicted for transmission path P1 in FIG. 15, the signal or power passes the bonding structure BS twice before it reaches the output terminal OP1 from the core circuit.

The configuration of the semiconductor structure 1500 provides several advantages. The input terminal IP1 and the output terminal OP1 of the transmission path P1 are arranged on a same side of the semiconductor structure 1500, i.e., the backside of the semiconductor wafer 301. No TSV is presented in the semiconductor wafer 300 thereby reducing production complexity and cost. The power/ground network or the signal network can be arranged on a same side of the semiconductor structure 1500, thereby simplifying the corresponding circuit design.

FIG. 16 is a schematic diagram showing a transmission path P2 of power and/or signals of a semiconductor device 1600, in accordance with some embodiments of the present disclosure. Referring to FIG. 16, in an inbound direction, for example, the transmission path P2 covers a route from an input terminal IP2 at a connector 804 in the interconnection area 340 of the semiconductor wafer 301, to a TSV 348 in the interconnection area 340 of the semiconductor wafer 301, the RDL 506, the bonding structure BS, a TSV 348 in the interconnection area 320 of the semiconductor wafer 300, the RDL 406, the nGAA transistor 110 or 120 in the die region 310 of the semiconductor wafer 300, the RDL 406, a TSV 348 in the interconnection area 320 of the semiconductor wafer 300, the bonding structure BS, the RDL 506, and to the GAA transistor 130 in the die region 330 of the semiconductor wafer 301. In the inbound direction depicted for transmission path P2 in FIG. 16, the signal or power passes the bonding structure BS twice before it reaches the core circuit, i.e., the GAA transistor 130 in the core wafer.

In an outbound direction, for example, the transmission path P2 covers a route from the GAA transistor 130 in the die region 330 of the semiconductor wafer 301, to the RDL 506, the bonding structure BS, a TSV 348 in the interconnection area 320 of the semiconductor wafer 300, the RDL 406, the nGAA transistor 110 or 120 in the die region 310 of the semiconductor wafer 300, the RDL 406, a TSV 348 in the interconnection area 320 of the semiconductor wafer 300, the bonding structure BS, the RDL 506, and a TSV 348 in the interconnection area 340 of the semiconductor wafer 301, to an output terminal OP2 such as a connector 804 in the interconnection area 340 of the semiconductor wafer 301. In the outbound direction depicted for transmission path P2 in FIG. 16, the signal or power passes the bonding structure BS twice before it reaches the output terminal OP2 from the core circuit.

The configuration of the semiconductor device 1600 provides several advantages. The input terminal IP2 and the output terminal OP2 of the transmission path P2 are both arranged on a same side of the semiconductor device 1600, i.e., the backside of the semiconductor wafer 301. Further, the TSVs 348 are present in the semiconductor wafer 300 to facilitate transmission in the front-to-back bonding scheme.

FIG. 17 is a schematic diagram showing a transmission path P3 of power and/or signals of a semiconductor device 1700, in accordance with some embodiments Referring to FIG. 17, in an inbound direction, for example, the transmission path P3 covers a route from an input terminal IP3 such as a connector 804 in the interconnection area 320 of the semiconductor wafer 300 to a TSV 348 in the interconnection area 320 of the semiconductor wafer 300, the RDL 406, the nGAA-transistor 110 or 120 in the die region 310 of the semiconductor wafer 300, the RDL 406, the bonding structure BS, the RDL 506, and to the GAA transistor 130 in the die region 330 of the semiconductor wafer 301. In the inbound direction depicted for transmission path P3 in FIG. 17, the signal or power passes the bonding structure BS only once before it reaches the core circuit, i.e., the GAA transistor 130 in the core wafer.

In an outbound direction, for example, the transmission path P3 covers a route from the GAA transistor 130 in the die region 330 of the semiconductor wafer 301 to the RDL 506, the bonding structure BS, the RDL 406, the nGAA transistor 110 or 120 in the die region 310 of the semiconductor wafer 300, the RDL 406, the bonding structure BS (including a connector 702), the RDL 506, and a TSV 348 in the interconnection area 340 of the semiconductor wafer 301 to the output terminal OP3 at a connector 804 in the interconnection area 340 of the semiconductor wafer 301. The input terminal IP3 and the output terminal OP3 are arranged on opposite sides of the semiconductor device 1700. In the outbound direction depicted for transmission path P3, the signal or power passes the bonding structure BS twice before it reaches the output terminal OP3 from the core circuit.

The configuration of the semiconductor device 1700 provides several advantages. The input terminal IP3 and the output terminal OP3 of the transmission path P3 are arranged on opposite sides of the semiconductor device 1700. The transmission path P3 allows for greater design flexibility, increased line pitch, and greater area/pitch of the input/output pads than existing semiconductor devices for high speed computation where the GAA transistors and nGAA transistors are integrated in a same wafer, or where the GAA transistors in a single wafer serving the purpose of both core and non-core circuits by having different gate dielectric thicknesses.

FIG. 18 is a schematic diagram showing a transmission path P4 of power and/or signals of a semiconductor device 1800, in accordance with some embodiments of the present disclosure. Referring to FIG. 18, in an inbound direction, the transmission path P4 covers a route from an input terminal IP4 such as a connector 804 in the interconnection area 320 of the semiconductor wafer 300, to the RDL 406, the nGAA transistor 110 or 120 in the die region 310 of the semiconductor wafer 300, the RDL 406, a TSV 348 in the interconnection area 320 of the semiconductor wafer 300, the bonding structure BS (including a connector 702), the RDL 506, and to the GAA transistor 130 in the die region 330 of the semiconductor wafer 301. In the inbound direction depicted for transmission path P4 in FIG. 18, the signal or power passes the bonding structure BS only once before it reaches the core circuit, i.e., the GAA transistor 130 in the core wafer.

In an outbound direction, the transmission path P4 covers a route from the GAA transistor 130 in the die region 330 of the semiconductor wafer 301, to the RDL 506, the bonding structure BS (including the connector 702), a TSV 348 in the interconnection area 320 of the semiconductor wafer 300, the RDL 406, the nGAA transistor 110 or 120 in the die region 310 of the semiconductor wafer 300, the RDL 406, and to the output terminal OP4 such as a connector 804 in the interconnection area 320 of the semiconductor wafer 300. In the outbound direction depicted for transmission path P4 in FIG. 18, the signal or power passes the bonding structure BS only once before it reaches the output terminal OP4 from the core circuit.

The configuration of the semiconductor device 1800 provides several advantages. The input terminal IP4 and the output terminal OP4 of the transmission path P4 are arranged on a same side of the semiconductor device 1800, i.e., the front side of the semiconductor wafer 300. No TSV is presented in the semiconductor wafer 301 thereby reducing production complexity and cost, as well as gaining more areas for active regions in the core circuit. The power/ground network or the signal network can be arranged on a same side of the semiconductor structure 1800, thereby simplifying the corresponding circuit design.

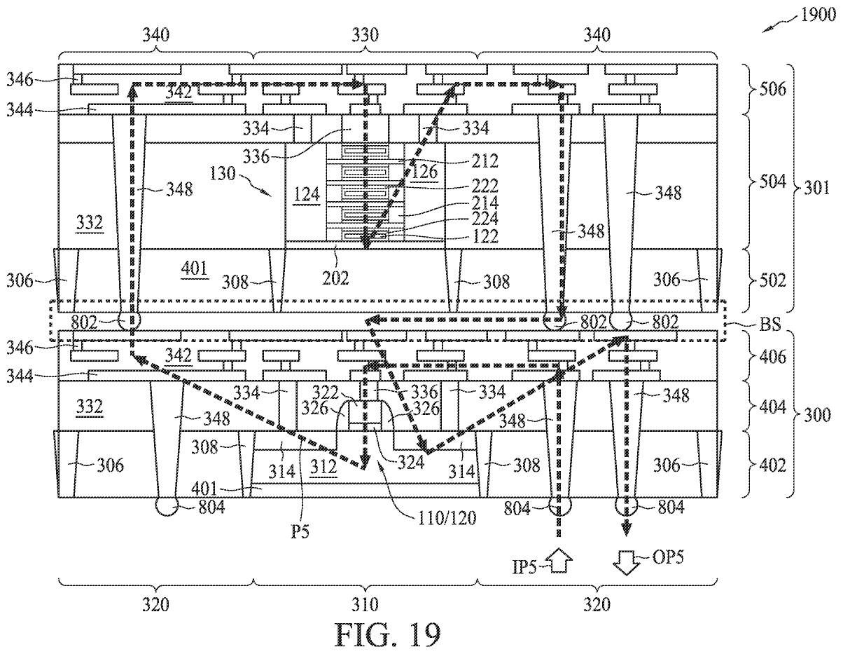

FIG. 19 is a schematic diagram showing a transmission path P5 of power and/or signals of a semiconductor device 1900, in accordance with some embodiments of the present disclosure. Referring to FIG. 19, the power or electrical signals flow in a direction of the transmission path P5. For example, in an inbound direction, the transmission path P5 covers a route from an input terminal IP5 at a connector 804 in the interconnection area 320 of the semiconductor wafer 300 to a TSV 348 in the interconnection area 320 of the semiconductor wafer 300, the RDL 406, the nGAA transistor 110 or 120 in the die region 310 of the semiconductor wafer 300, the RDL 406, the bonding structure BS (including a connector 802), a TSV 348 in the interconnection area 340 of the semiconductor wafer 301, the RDL 506, and to the GAA transistor 130 in the die region 330 of the semiconductor wafer 301. In the inbound direction depicted for transmission path P5, the signal or power passes the bonding structure BS only once before it reaches the core circuit, i.e., the GAA transistor 130 in the core wafer.

In an outbound direction, the transmission path P5 covers a route from the GAA transistor 130 in the die region 330 of the semiconductor wafer 301 to the RDL 506, a TSV 348 in the interconnection area 340 of the semiconductor wafer 301, the bonding structure BS (including a connector 802), the RDL 406, the nGAA transistor 110 or 120 in the die region 310 of the first semiconductor wafer 300, the RDL 406, and a TSV in the interconnection area 320 of the semiconductor wafer 300 to the output terminal OP5 such as a connector 804 in the interconnection area 320 of the semiconductor wafer 300. In the outbound direction depicted for transmission path P5 in FIG. 19, the signal or power passes the bonding structure BS only before it reaches the output terminal OP5 from the core circuit.

The configuration of the semiconductor device 1900 provides several advantages. The input terminal IP5 and the output terminal OP5 of the transmission path P5 are arranged on the same side of the semiconductor device 1900, i.e., the backside of the semiconductor wafer 300. TSVs 348 are presented in both semiconductor wafers 301 and 300 in order to facilitate signal/power transmission and also to accommodate the front-to-back bonding structure. The power/ground network or the signal network can be arranged on a same side of the semiconductor structure 1900, thereby simplifying the corresponding circuit design.

The present disclosure discusses a semiconductor structure or a semiconductor device including a core circuit formed of GAA transistors and a non-core circuit formed of nGAA transistors. The GAA transistors and the nGAA transistors are formed separately in respective semiconductor wafers. The semiconductor wafer with the core circuit having GAA transistors is bonded to the semiconductor wafer with the non-core circuit having the nGAA transistors. The GAA transistor has a first gate dielectric layer including a first thickness, and the nGAA transistor has a second gate dielectric layer including a second thickness greater than the first thickness. Among the various types of nGAA transistors, a planar-type transistor has a gate dielectric layer including a thickness greater than a thickness of the gate dielectric layer of a fin-type transistor. After a dicing operation, the semiconductor structure or the semiconductor device is formed of a first substrate having GAA transistors in the core circuit bonded to a second substrate having the nGAA transistors in the non-core circuit. The core circuit can operate to perform high-speed tasks with advanced transistors, while the non-core circuit can operate under a higher working voltage without obstacles of integration with the core circuit. Therefore, the proposed semiconductor structure or semiconductor device can include the most advanced core circuit for the latest AI- or ML-related applications.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages as those of the embodiments introduced herein. Those skilled in the art should also realize that such equivalent constructions do not depart from the spirit and scope of the present disclosure, and that they may make various changes, substitutions, and alterations to the embodiments disclosed herein without departing from the spirit and scope of the present disclosure.

What is claimed is:

1. A semiconductor structure comprising:
a first substrate including a plurality of first-type transistors formed of planar-type transistors or fin-type transistors, wherein a gate silicon oxide layer of each of the planar-type transistors has a first thickness, and a gate silicon oxide layer of each of the fin-type transistors has a second thickness; and
a second substrate bonded to the first substrate and including a plurality of second-type transistors formed of gate-all-around (GAA) transistors, wherein a gate silicon oxide layer of each of the GAA transistors has a third thickness,
wherein the third thickness is less than the first thickness or the second thickness.

2. The semiconductor structure of claim 1, wherein the third thickness is less than about 1 nm.

3. The semiconductor structure of claim 1, wherein the second thickness is substantially equal to or greater than about 1.5 nm.

4. The semiconductor structure of claim 1, wherein the first thickness is substantially equal to or greater than about 1.8 nm.

5. The semiconductor structure of claim 1, wherein the first-type transistors operate under a first voltage, and the second-type transistors operate under a second voltage less than the first voltage.

6. The semiconductor structure of claim 1, further comprising:
a bonding structure between the first substrate and the second substrate, wherein the first-type transistors and the second-type transistors are interconnected to allow a power signal or an electrical signal inputted from an input terminal to arrive at the second-type transistors by first passing the bonding structure.

7. The semiconductor structure of claim 6, wherein the first-type transistors and the second-type transistors are further interconnected to allow the power signal or the electrical signal inputted from the input terminal to arrive at the second-type transistors by entering the first-type transistors prior to passing the bonding structure.

8. The semiconductor structure of claim 7, wherein the first-type transistors and the second-type transistors are further interconnected to allow the power signal or the electrical signal outputted from the second-type transistors to an output terminal to arrive at the output terminal by first passing the bonding structure.

9. The semiconductor structure of claim 6, further comprising a through substrate via (TSV) in at least one of the first substrate and the second substrate, and electrically connected to the bonding structure.

10. The semiconductor structure of claim 6, wherein the bonding structure comprises one of a hybrid bonding layer, an under bump metallization, a conductive bump, or a micro bump.

11. The semiconductor structure of claim 1, wherein the second-type transistors form a processor for artificial intelligence (AI) machine-learning or AI deep-learning applications.

12. The semiconductor structure of claim 1, wherein the second substrate comprises at least one of an I/O circuit, an analog circuit, a power circuit and a memory circuit.

13. A semiconductor device comprising:
a first substrate including a plurality of first-type transistors formed of planar-type transistors or fin-type transistors, wherein the first-type transistors operate under a first voltage and wherein each of the plurality of first-type transistors has a first gate silicon oxide layer stacking with a first high-k dielectric layer, the first gate silicon oxide layer and the first high-k dielectric layer having a first combined thickness; and
a second substrate bonded to the first substrate and including a plurality of second-type transistors formed of gate-all-around (GAA) transistors, wherein the second-type transistors operate under a second voltage less than the first voltage and wherein each of the plurality of second-type transistors has a second gate silicon oxide layer stacking with a second high-k dielectric layer, the second gate silicon oxide layer and the second high-k dielectric layer having a second combined thickness,
wherein the first combined thickness is greater than the second combined thickness.

14. The semiconductor device of claim 13, wherein the second voltage is supplied to the second-type transistors through the first-type transistors and passing a bonding structure between the first substrate and the second substrate.

15. The semiconductor device of claim 14, wherein the bonding structure comprises one of a hybrid bonding layer, an under bump metallization, a conductive bump, or a micro bump

16. The semiconductor device of claim 13, wherein the second combined thickness is less than the first combined thickness by at least 50% of the first combined thickness.

17. The semiconductor device of claim 13, wherein at least one of the first substrate and the second substrate comprises a TSV electrically coupled to the other of the first substrate and the second substrate.

18. A method, comprising:
forming a plurality of first die regions on a first semiconductor wafer, wherein each of the first die regions comprises a plurality of first-type transistors formed of planar-type transistors or fin-type transistors, wherein a gate silicon oxide layer of each of the planar-type transistors has a first thickness, and a gate silicon oxide layer of each of the fin-type transistors has a second thickness;
forming a plurality of second die regions on a second semiconductor wafer, wherein each of the second die regions comprises a plurality of second-type transistors formed of gate-all-around (GAA) transistors (FIG. 1C, 130), wherein a gate silicon oxide layer (FIG. 1C, 125) of each of the GAA transistors has a third thickness; and
bonding the first semiconductor wafer to the second semiconductor wafer by electrically coupling each of the first die regions to a corresponding one of the second die regions,
wherein the third thickness is less than the first thickness or the second thickness.

19. The method of claim 18, further comprising:
forming through-substrate vias (TSVs) in a first interconnection area of the first semiconductor wafer prior to bonding.

20. The method of claim 18, prior to bonding the first semiconductor wafer to the second semiconductor wafer, further comprising:
forming a portion of a bonding structure at a front side or a back side of the first semiconductor wafer; and
forming a portion of the bonding structure at a front side or a back side of the second semiconductor wafer.
